(19) United States
(12) Patent Application Publication
(10) Pub. No.: US 2026/0129834 A1
(43) Pub. Date: May 7, 2026

(54) SEMICONDUCTOR DEVICE

(71) Applicant: SAMSUNG ELECTRONICS CO., LTD., Suwon-si (KR)

(72) Inventors: Moonyoung JEONG, Suwon-si (KR); Sangho LEE, Suwon-si (KR); Jae Hyun CHOI, Suwon-si (KR)

(73) Assignee: SAMSUNG ELECTRONICS CO., LTD., Suwon-si (KR)

(21) Appl. No.: 19/217,090

(22) Filed: May 23, 2025

(30) Foreign Application Priority Data
Nov. 6, 2024 (KR) 10-2024-0156558

(51) Int. Cl. H10B 12/00; H01L 23/00; H01L 25/00; H01L 25/065; H01L 25/18; H10B 80/00

(52) U.S. Cl. CPC H10B 12/315; H10B 12/05; H10B 80/00; H10W 90/00; H10W 80/312; H10W 80/327; H10W 90/792

(57) ABSTRACT

A semiconductor device includes a substrate, a bit line positioned on the substrate and extending in a first direction, word lines extending in a second direction, a first active pattern and a second active pattern positioned between the word lines and spaced apart in the first direction, a cell capacitor positioned on the first active pattern and the second active pattern, and shield gates positioned at a level between the word lines and the cell capacitor. Each of the first active pattern and the second active pattern includes a first dopant region connected to the bit line, a second dopant region connected to the cell capacitor, and a channel region positioned between the first dopant region and the second dopant region. The shield gates overlap the second dopant region of at least one of the first active pattern and the second active pattern in the first direction.

### CROSS-REFERENCE TO RELATED APPLICATION

This application claims priority to and the benefit of Korean Patent Application No. 10-2024-0156558 filed in the Korean Intellectual Property Office on Nov. 6, 2024, the entire contents of which are incorporated herein by reference.

### BACKGROUND OF THE DISCLOSURE

### 1. Field

The present disclosure relates to a semiconductor device.

### 2. Description of the Related Art

There is a need for technologies to increase the degrees of integration of semiconductor devices. In the case of two-dimensional semiconductor devices, the degrees of integration are mainly determined by the areas occupied by unit memory cells, and the degrees of integration in this aspect may depend on the levels of micropatterning techniques.

By the way, the micropatterning techniques require expensive equipment. Therefore, although the degrees of integration of two-dimensional semiconductor devices are increasing, it is still limited. Accordingly, three-dimensional memory devices having memory cells arranged in three dimensions are being proposed.

As components which are included in semiconductor memory devices become more integrated and miniaturized, it is important to minimize the influence between components included in semiconductor devices to improve the operating performance of the semiconductor devices.

### SUMMARY

The present disclosure attempts to provide a semiconductor device with improved reliability and productivity.

A semiconductor device according to an embodiment includes a substrate, a bit line that is positioned on the substrate and extends in a first direction, a plurality of word lines that extend in a second direction intersecting the first direction, a first active pattern and a second active pattern that are positioned between the plurality of word lines and spaced apart in the first direction, a cell capacitor that is positioned on the first active pattern and the second active pattern, and a plurality of shield gates that are positioned at a level between the plurality of word lines and the cell capacitor, and each of the first active pattern and the second active pattern includes a first dopant region that is connected to the bit line, a second dopant region that is connected to the cell capacitor, and a channel region that is positioned between the first dopant region and the second dopant region, and the plurality of shield gates overlap the second dopant region of at least one of the first active pattern and the second active pattern in the first direction.

A semiconductor device according to an embodiment includes a substrate that includes a cell array region and a peripheral circuit region, a bit line that is positioned on the cell array region and extends in a first direction, a plurality of word lines that extend in a second direction intersecting the first direction, a first active pattern and a second active pattern that are positioned on the plurality of word lines and spaced apart in the first direction, a back gate electrode that is positioned between the first active pattern and the second active pattern and extends in the second direction, a cell capacitor that is positioned on the first active pattern and the second active pattern, and a plurality of shield gates that overlap at least one of the plurality of word lines and the back gate electrode in a vertical direction intersecting the first direction and the second direction, and each of the first active pattern and the second active pattern includes a first dopant region that is connected to the bit line, a second dopant region that is connected to the cell capacitor, and a channel region that is positioned between the first dopant region and the second dopant region, and the plurality of shield gates overlap the second dopant region of at least one of the first active pattern and the second active pattern in the first direction.

A semiconductor device according to an embodiment includes a substrate that includes a cell array region and a peripheral circuit region, a peripheral circuit structure that includes a peripheral circuit which is positioned on the substrate, and a peripheral circuit wiring line which is connected to the peripheral circuit, and a cell structure that overlaps the peripheral circuit structure in a vertical direction, and the cell structure includes a bit line that is positioned on the substrate and extends in a first direction intersecting the vertical direction, a plurality of word lines that extend in a second direction intersecting the first direction and the vertical direction, a plurality of active patterns that are positioned between the plurality of word lines and spaced apart in the first direction, a back gate electrode that is positioned between the plurality of active patterns and extends in the second direction, a cell capacitor that is positioned on the plurality of active patterns, a first shield gate that overlaps the back gate electrode in the vertical direction, and a second shield gate that overlaps the plurality of word lines in the vertical direction, and each of the plurality of active patterns includes the following: a first dopant region that is connected to the bit line, a second dopant region that is connected to the cell capacitor, and a channel region that is positioned between the first dopant region and the second dopant region, and each of the first shield gate and the second shield gate overlaps the second dopant region in the first direction.

According to the embodiments, since a shield gate is formed such that it is positioned so as to overlap a dopant region of an active pattern which is connected to a capacitor, gate induced drain leakage (GIDL) of a memory transistor can decrease, and the current value of the memory transistor in the on state can improve.

### BRIEF DESCRIPTION OF THE DRAWINGS

FIG. 1 is a plan view of a semiconductor device according to an embodiment.

FIG. 2 is a plan view illustrating some components of the semiconductor device according to the embodiment.

FIG. 3 is a plan view illustrating some components of FIG. 2.

FIG. 4 is a cross-sectional view illustrating a cross section taken along lines A-A′ and B-B′ of FIG. 1.

FIG. 5 is a cross-sectional view illustrating a cross section taken along line C-C′ of FIG. 1.

FIG. 6 is a cross-sectional view illustrating a cross section taken along lines D-D′ and E-E′ of FIG. 1.

FIG. 7 is a partial enlarged view of region P1 of FIG. 5.

FIGS. 8 to 17 are cross-sectional views illustrating cross sections of semiconductor devices according to some embodiments.

FIGS. 18 and 19 are plan views illustrating some components of semiconductor devices according to some embodiments.

FIG. 20 is a cross-sectional view illustrating a cross section of a semiconductor device according to some embodiments.

FIG. 21 is a cross-sectional view illustrating a cross section of a semiconductor device according to some embodiments.

FIG. 22 is an enlarged view of region R1 of FIG. 21.

FIGS. 23 and 24 are cross-sectional views illustrating cross sections of semiconductor devices according to some embodiments.

FIGS. 25 to 33 are cross-sectional views for explaining a method of manufacturing the semiconductor device according to the embodiment.

### DETAILED DESCRIPTION

In the following detailed description, only certain embodiments have been shown and described, simply by way of illustration. The present invention can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, in the entire specification, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

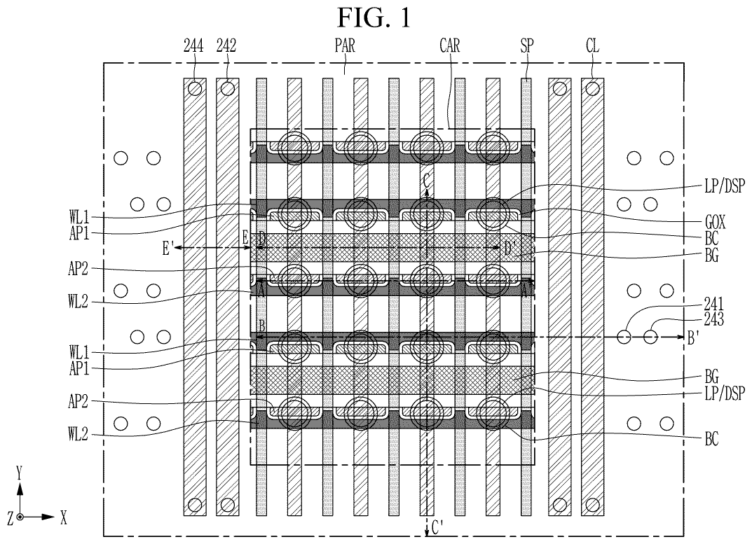

Hereinafter, a semiconductor device according to an embodiment will be described below with reference to FIGS. 1 to 7.

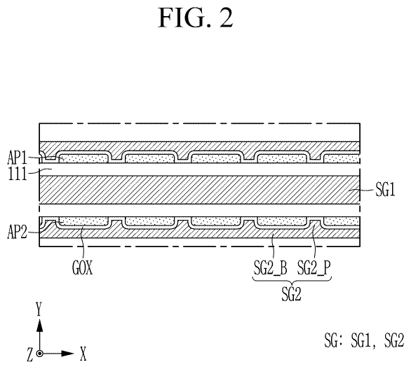

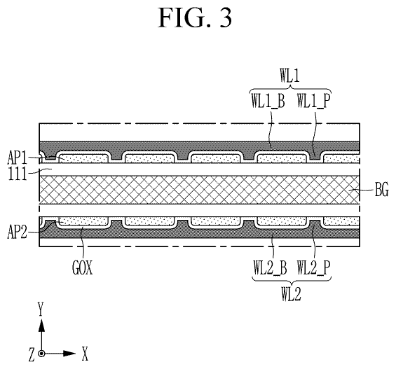

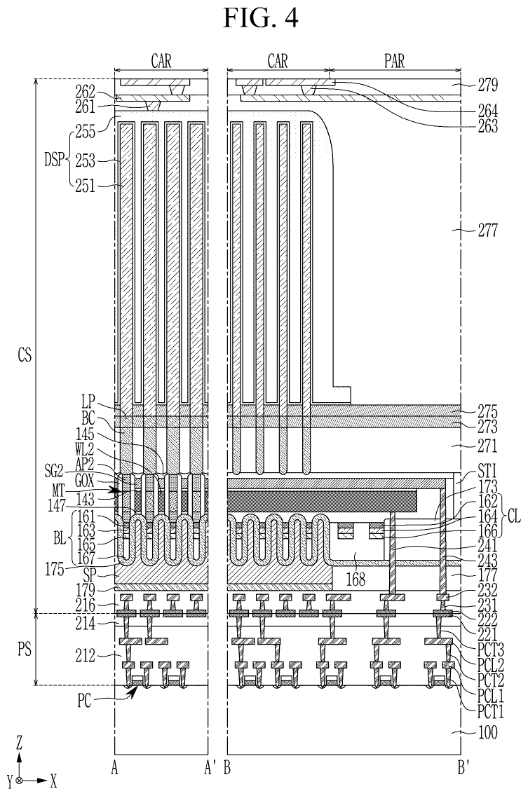

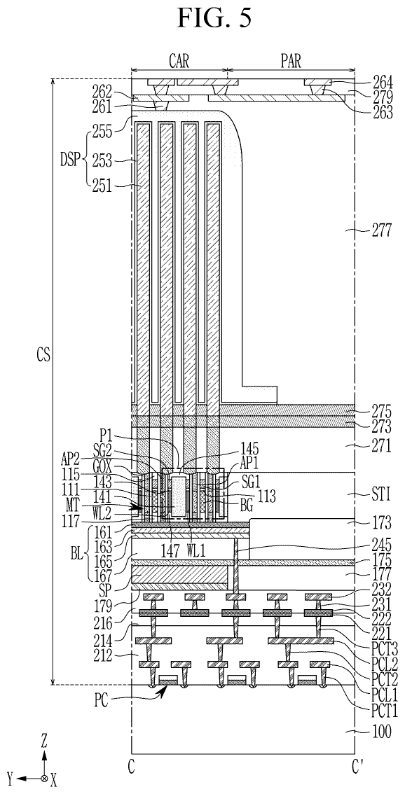

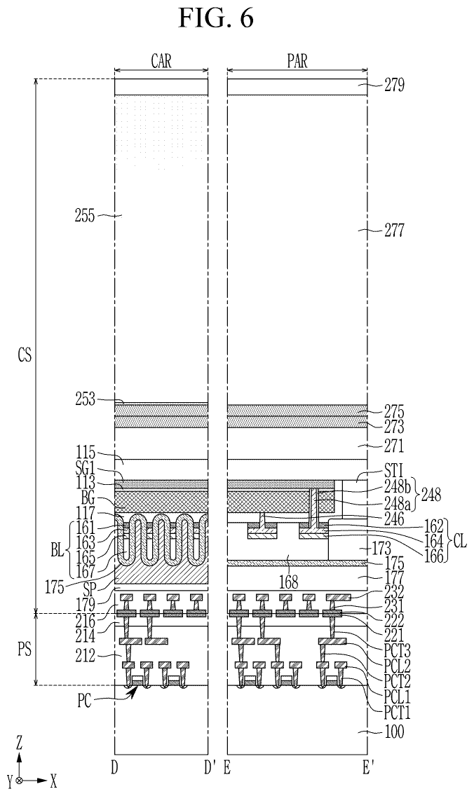

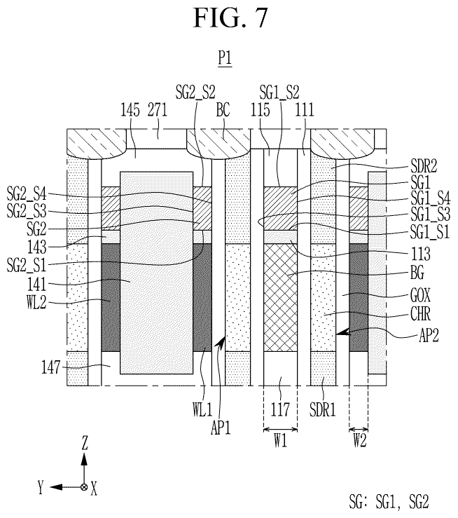

FIG. 1 is a plan view of a semiconductor device according to an embodiment. FIG. 2 is a plan view illustrating some components of the semiconductor device according to the embodiment. FIG. 3 is a plan view illustrating some components of FIG. 2. FIG. 4 is a cross-sectional view illustrating a cross section taken along lines A-A′ and B-B′ of FIG. 1. FIG. 5 is a cross-sectional view illustrating a cross section taken along line C-C′ of FIG. 1. FIG. 6 is a cross-sectional view illustrating a cross section taken along lines D-D′ and E-E′ of FIG. 1. FIG. 7 is a partial enlarged view of region P1 of FIG. 5.

In FIGS. 2 and 3, in order to illustrate the arrangement relationship of some components of the components included in the semiconductor device, the other components are not shown.

A semiconductor device according to an embodiment may include a plurality of memory cells including vertical channel transistors (VCTs). However, this is an example, and semiconductor devices according to embodiments are not limited thereto and may be variously changed.

Referring to FIGS. 1 to 7, a semiconductor device according to some embodiments may include a substrate 100, and a peripheral circuit structure PS and a cell structure CS which are positioned on the substrate 100.

The substrate 100 may include a cell array region CAR, and a peripheral circuit region PAR defined around the cell array region CAR. For example, the peripheral circuit region PAR may be positioned adjacent to the cell array region CAR, and surround the cell array region CAR. However, the arrangement relationship of the cell array region CAR and the peripheral circuit region PAR is not limited thereto, and may be variously changed.

In the cell array region CAR, a plurality of memory cells which includes memory transistors MT and cell capacitors DSP, word lines WL and bit lines BL which are connected to them, and so on may be positioned, and in the peripheral circuit region PAR, a plurality of contacts 241 and 243 and contact wiring lines CL connected to the components positioned in the cell array region CAR may be positioned.

A memory cell may include one memory transistor MT and one cell capacitor DSP. Depending on whether there is any charge stored in the cell capacitor DSP, two states distinguishable from each other may be determined, and the cell capacitor DSP may act as a memory element.

The gate electrode of the memory transistor MT may be connected to a word line WL, and a first source/drain electrode of the memory transistor MT may be connected to one terminal of the cell capacitor DSP, and a second source/drain electrode of the memory transistor MT may be connected to a bit line BL. This will be described below in detail.

The substrate 100 may be a silicon substrate, or may contain silicon germanium, indium antimonide, a lead tellurium compound, indium arsenide, indium phosphide, gallium arsenide, or gallium antimonide, but is not limited thereto, and the material which is contained in the substrate 100 may be variously changed.

In the embodiment, the peripheral circuit structure PS and the cell structure CS which are positioned on the substrate 100 may be positioned so as to overlap in a vertical direction. For example, the peripheral circuit structure PS and the cell structure CS may be sequentially stacked on the substrate 100. In other words, the cell structure CS may be positioned on the peripheral circuit structure PS. However, the present disclosure is not limited thereto, and the stacking relationship of the cell structure CS and the peripheral circuit structure PS may be variously changed. For example, the cell structure CS may be positioned adjacent to and side by side with the peripheral circuit structure PS in a horizontal direction. As another example, the cell structure CS may be positioned below the peripheral circuit structure PS so as to overlap the peripheral circuit structure in the vertical direction.

Hereinafter, the configuration and structure of the semiconductor device according to the embodiment will be described in detail.

The embodiment will be described on the assumption of the structure in which the cell structure CS is positioned on the peripheral circuit structure PS.

The peripheral circuit structure PS may be positioned on the substrate 100. The peripheral circuit structure PS may be positioned between the substrate 100 and the cell structure CS.

The peripheral circuit structure PS may be positioned throughout the cell array region CAR and peripheral circuit region PAR of the substrate 100. In other words, a portion of the peripheral circuit structure PS may be positioned on the cell array region CAR of the substrate 100, and the other portion may be positioned on the peripheral circuit region PAR.

Although not shown in the drawings, the peripheral circuit structure PS may include a core region and a peri region. The core region and the peri region may be collectively referred to as the logic region or the peripheral circuit region.

The core region may include a core bank, and the core bank may include core circuits such as a word line driver, a sense amplifier, a row decoder, a column decoder, and a read/write circuit (R/W circuit).

The peri region may include peri circuits such as a timing register, an address register, a data input register, a data output register, and a data input/output terminal.

The peripheral circuit structure PS may include a peripheral circuit PC for driving the components positioned in the cell structure CS. For example, the peripheral circuit PC may include the core circuits and/or the peri circuits mentioned above.

The peripheral circuit structure PS may include the peripheral circuit PC, peripheral circuit contacts PCT1, PCT2, and PCT3, peripheral circuit wiring lines PCL1 and PCL2, a peripheral circuit insulating layer 212, a first bonding insulating layer 214, and a plurality of first bonding pads 221.

The peripheral circuit PC may be positioned on the substrate 100. The peripheral circuit PC may include, for example, a sensing transistor, a transfer transistor, a driving transistor, etc. However, the type of the transistor of the peripheral circuit PC may be variously changed depending on the design of the semiconductor device.

The peripheral circuit insulating layer 212 may cover the peripheral circuit PC. In other words, the peripheral circuit insulating layer 212 may cover the side surfaces and upper surface of the peripheral circuit PC. The peripheral circuit insulating layer 212 may contain an insulating material. For example, the peripheral circuit insulating layer 212 may contain silicon oxide, silicon nitride, silicon oxynitride, and/or a low-dielectric constant material. However, the present disclosure is not limited thereto.

The peripheral circuit contacts PCT1, PCT2, and PCT3 and the peripheral circuit wiring lines PCL1 and PCL2 may be positioned inside the peripheral circuit insulating layer 212.

The first peripheral circuit wiring line PCL1 may be connected to the peripheral circuit PC through the first peripheral circuit contact PCT1. The first peripheral circuit wiring line PCL1 may be connected to at least a source/drain region of the peripheral circuit PC positioned on one side, through the first peripheral circuit contact PCT1. The first peripheral circuit wiring line PCL1 and the second peripheral circuit wiring line PCL2 may be connected by the second peripheral circuit contact PCT2.

Although it is shown in the drawings that, in the embodiment, the peripheral circuit insulating layer 212 includes a single layer, the present disclosure is not limited thereto, and the peripheral circuit insulating layer 212 may include multiple layers containing the same material and/or different materials.

When the peripheral circuit insulating layer 212 includes multiple layers, at least some of the first peripheral circuit contact PCT1, the second peripheral circuit contact PCT2, the third peripheral circuit contact PCT3, the first peripheral circuit wiring line PCL1, the second peripheral circuit wiring line PCL2, and a third peripheral circuit wiring line PCL3 may be positioned in substantially the same layer or in different layers.

The first bonding insulating layer 214 may be positioned on the peripheral circuit insulating layer 212. The first bonding insulating layer 214 may contain an insulating material. For example, the first bonding insulating layer 214 may contain silicon carbonitride, but is not limited thereto. As another example, the first bonding insulating layer 214 may contain at least one of silicon oxide, silicon oxynitride, silicon oxycarbonitride, and silicon nitride.

The third peripheral circuit contact PCT3 may be positioned inside the peripheral circuit insulating layer 212 and the first bonding insulating layer 214. In other words, a portion of the third peripheral circuit contact PCT3 may be positioned in the peripheral circuit insulating layer 212, and the other portion may be positioned inside the first bonding insulating layer 214.

The plurality of first bonding pads 221 may be positioned inside the first bonding insulating layer 214. The first bonding insulating layer 214 may surround the plurality of first bonding pads 221. The first bonding insulating layer 214 may surround the side surfaces and lower surfaces of the first bonding pads 221. The upper surface of the first bonding insulating layer 214 may be positioned substantially at the same level as that of the upper surfaces of the plurality of first bonding pads 221, and the first bonding insulating layer 214 may expose the upper surfaces of the plurality of first bonding pads 221. A first bonding pad 221 may be connected to the second peripheral circuit wiring line PCL2 through the third peripheral circuit contact PCT3.

In the embodiment, the peripheral circuit structure PS and the cell structure CS may be a semiconductor device bonded by a Cu-to-Cu (C2C) wafer bonding. For example, the peripheral circuit structure PS and the cell structure CS may be a semiconductor device bonded by a hybrid copper bonding (HCB) method. However, the bonding method of the peripheral circuit structure PS and the cell structure CS is not limited thereto, and may be variously changed.

Specifically, the peripheral circuit structure PS may include two surfaces opposing each other. One surface of the two surfaces of the peripheral circuit structure PS may be a surface facing the cell structure CS, and the other surface of the peripheral circuit structure PS may be a surface facing the substrate 100.

Here, one surface of the peripheral circuit structure PS may refer to the front side of the peripheral circuit structure PS, and the other surface of the peripheral circuit structure PS may refer to the back side of the peripheral circuit structure PS.

Also, the cell structure CS may include one surface and another surface opposing each other. One surface of the cell structure CS may be a surface facing the peripheral circuit structure PS, and another surface may be the opposite surface to one surface. Here, one surface of the cell structure CS may refer to the back side of the cell structure CS, and another surface of the cell structure CS may refer to the front side of the cell structure CS.

In the embodiment, one surface of the peripheral circuit structure PS adjacent to the cell structure CS may be a bonding surface with the cell structure CS. Also, one surface of the cell structure CS adjacent to the peripheral circuit structure PS may be a bonding surface with the peripheral circuit structure PS. In other words, one surface of the peripheral circuit structure PS and one surface of the cell structure CS may be the bonding surfaces of the peripheral circuit structure PS and the cell structure CS. One surface of the peripheral circuit structure PS and one surface of the cell structure CS may constitute the interface of the peripheral circuit structure PS and the cell structure CS.

Specifically, the cell structure CS may include a second bonding insulating layer 216 which is in contact with the first bonding insulating layer 214 of the peripheral circuit structure PS. The second bonding insulating layer 216 may contain the same material as that of the first bonding insulating layer 214 which is positioned in the above-described peripheral circuit structure PS, and may be positioned on the first bonding insulating layer 214.

Inside the second bonding insulating layer 216 positioned in the cell structure CS, second bonding pads 222 may be positioned. The second bonding insulating layer 216 may surround the plurality of second bonding pads 222. The second bonding insulating layer 216 may surround the side surfaces and upper surfaces of the second bonding pads 222. The lower surface of the second bonding insulating layer 216 may be positioned substantially at the same level as that of the lower surfaces of the plurality of second bonding pads 222, and the second bonding insulating layer 216 may expose the lower surfaces of the plurality of second bonding pads 222.

The plurality of second bonding pads 222 which is positioned inside the second bonding insulating layer 216 may form a metallic bond in a state where they are in direct contact with the plurality of first bonding pads 221 positioned inside the first bonding insulating layer 214. The upper surfaces of the plurality of first bonding pads 221 and the lower surfaces of the plurality of second bonding pads 222 may be in contact. The plurality of first bonding pads 221 and the plurality of second bonding pads 222 may be positioned at the interface of the peripheral circuit structure PS and the cell structure CS, and may be in contact with each other.

Further, the first bonding insulating layer 214 which is positioned in the peripheral circuit structure PS and a second bonding insulating layer 216 which is positioned in the cell structure CS may be in contact with each other, thereby forming a junction insulating layer.

Accordingly, one surface of the cell structure CS and one surface of the peripheral circuit structure PS may be bonded. In other words, the plurality of first bonding pads 221 and the first bonding insulating layer 214 which are positioned in the peripheral circuit structure PS may constitute one surface or bonding surface of the peripheral circuit structure PS, and the plurality of second bonding pads 222 and the second bonding insulating layer 216 which are positioned in the cell structure CS may constitute one surface or bonding surface of the cell structure CS.

The first bonding pads 221 of the peripheral circuit structure PS and the second bonding pads 222 of the cell structure CS may be bonded to provide an electrical connection path between the peripheral circuit structure PS and the cell structure CS. For example, cell connection wiring lines 232 connected to the components included in the cell structure CS may be connected to the peripheral circuit PC and/or the peripheral circuit wiring lines PCL1 and PCL2 included in the peripheral circuit structure PS by the first bonding pads 221 and the second bonding pads 222.

The cell structure CS may include a cell connection wiring contact 231 and a cell connection wiring line 232 positioned inside the second bonding insulating layer 216. The cell connection wiring line 232 may be connected to components positioned in the cell structure CS, and the cell connection wiring contact 231 may connect a second bonding pad 222 and the cell connection wiring line 232. For example, the cell connection wiring line 232 may be connected to the plurality of memory cells including the memory transistors MT and the cell capacitors DSP, the word line WL and the bit line BTL connected to the memory cells, and so on positioned in the cell structure CS.

Each of the peripheral circuit contacts PCT1, PCT2, and PCT3 and the peripheral circuit wiring lines PCL1 and PCL2 which are positioned in the peripheral circuit structure PS and the cell connection wiring contact 231 and the cell connection wiring line 232 which are positioned in the cell structure CS may contain a conductive material. For example, each may contain aluminum (Al), tungsten (W), titanium (Ti), copper (Cu), tantalum (Ta), etc. However, the present disclosure is not limited thereto.

In the embodiment, the cell structure CS may include a plurality of bit lines BL, a plurality of word lines WL1 and WL2 that are positioned on the plurality of bit lines BL and extend across the plurality of bit lines BL, a plurality of active patterns AP1 and AP2 that are positioned between the plurality of word lines WL1 and WL2, a back gate electrode BG that is positioned between the plurality of active patterns AP1 and AP2 and extends across the plurality of bit lines BL, a buried contact BC that is positioned on the plurality of active patterns AP1 and AP2, a landing pad LP that is positioned on the buried contact BC, a cell capacitor DSP that is positioned on the landing pad LP, and a plurality of shield gates SG that are positioned at a level between the plurality of word lines WL1 and WL2 and the cell capacitor DSP and overlap at least a portion of the active patterns AP1 and AP2 in a horizontal direction.

The semiconductor device according to the embodiment may include the plurality of bit lines BL. The plurality of bit lines BL may extend in parallel with each other in a second direction Y that intersects a first direction X parallel with the substrate 100. The plurality of bit lines BL may be positioned on the substrate 100 so as to be spaced apart from each other in the first direction X.

In the embodiment, the plurality of bit lines BL may extend in the second direction Y from the cell array region CAR to the peripheral circuit region PAR. Accordingly, the end portions of the bit lines BL may be positioned in the peripheral circuit region PAR positioned on both sides of the cell array region CAR in the second direction Y. An end portion of a bit line BL which is positioned in the peripheral circuit region PAR may be connected to a bit line contact 245.

A bit line BL may include a polysilicon layer 161, a first metal layer 163, a second metal layer 165, and a bit line capping layer 167.

The polysilicon layer 161 may contain polysilicon doped with an impurity, and the first metal layer 163 and the second metal layer 165 may contain a conductive material. For example, the first metal layer 163 may contain a conductive metal nitride (for example, titanium nitride, nitride tantalum, or the like), and the second metal layer 165 may contain a metal (for example, tungsten, titanium, tantalum, or the like).

Also, any one of the first metal layer 163 and the second metal layer 165 may contain metal silicide such as titanium silicide, cobalt silicide, or nickel silicide. However, the materials which are contained in the first metal layer 163 and the second metal layer 165 are not limited thereto, and may be variously changed.

The bit line capping layer 167 may contain an insulating material such as silicon nitride or silicon oxynitride.

In some embodiments, the bit lines BL may contain a two-dimensional or three-dimensional material, and may contain, for example, graphene which is a carbon-based two-dimensional material, carbon nanotube which is a three-dimensional material, or a combination thereof.

The plurality of bit lines BL may be positioned adjacent to the peripheral circuit structure PS. As the plurality of bit lines BL are positioned adjacent to the peripheral circuit structure PS, electrical connection paths between the bit lines BL and peripheral circuits PC may decrease.

The semiconductor device according to the embodiment may further include a shield pattern SP and a spacer insulating layer 175 which are positioned between the peripheral circuit structure PS and the cell structure CS.

The shield pattern SP may be positioned between the peripheral circuit structure PS and the bit line BL. Further, the shield pattern SP may be positioned between the bit lines BL and extend in the second direction Y. In other words, the shield pattern SP may be arranged alternately with the bit lines BL in the first direction X.

The spacer insulating layer 175 may be positioned on the bit lines BL so as to conform to them. The spacer insulating layer 175 may cover both side surfaces and upper surface of each of the plurality of bit lines BL. The spacer insulating layer 175 may define a gap region between the plurality of bit lines BL. The gap region of the spacer insulating layer 175 may extend in the second direction Y so as to be in parallel with the bit lines BL.

The shield pattern SP may contain a conductive material. For example, the shield pattern SP may contain a metal material such as tungsten (W), titanium (Ti), nickel (Ni), and cobalt (Co). As another example, the shield pattern SP may include a conductive two-dimensional (2D) material such as graphene. However, the shield pattern SP is not limited thereto.

The spacer insulating layer 175 may contain an insulating material. For example, the spacer insulating layer may contain silicon oxide, silicon nitride, silicon oxynitride, and/or a low-dielectric constant material.

The shield pattern SP may be positioned on the spacer insulating layer 175. The shield pattern SP may be positioned inside the gap region of the spacer insulating layer 175.

As shown in FIGS. 4 to 6, the shield pattern SP may include line portions which are positioned between the bit lines BL adjacent to each other, and a connection portion that connects the line portions in common.

Specifically, the line portions of the shield pattern SP may be positioned between the bit lines BL, and positioned inside a plurality of gap regions defined by the spacer insulating layer 175. Accordingly, the side surfaces of the line portions of the shield pattern SP and the bit lines BL may be spaced apart with the spacer insulating layer 175 interposed therebetween.

The connection portion of the shield pattern SP may be connected to the line portions, and integrated with the line portions. The connection portion of the shield pattern SP may be positioned on the line portions so as to connect line portions, positioned between the bit lines BL adjacent to each other, to each other. However, the present disclosure is not limited thereto, and in some embodiments, the line portions and connection portion of the shield pattern SP may be formed as separate components.

As shown in FIG. 1, each line portion of the shield pattern SP may be positioned in the cell array region CAR and the peripheral circuit region PAR. In other words, each line portion of the shield pattern SP may extend from the cell array region CAR to the peripheral circuit region PAR. Accordingly, the end portions of each line portion of the shield pattern SP may be positioned in the peripheral circuit region PAR positioned on both sides of the cell array region CAR in the second direction Y.

Although not shown in the drawings, the connection portion of the shield pattern SP may extend from the cell array region CAR to the peripheral circuit region PAR. Accordingly, the end portions of the connection portion of the shield pattern SP may be positioned in the peripheral circuit region PAR. The connection portion of the shield pattern SP which is positioned in the peripheral circuit region PAR may be connected to a shield pattern contact (not shown in the drawings).

The semiconductor device according to the embodiment may further include a plurality of contact wiring lines CL which are positioned in the peripheral circuit region PAR and a contact wiring line capping layer 168 which covers the contact wiring lines CL.

The plurality of contact wiring lines CL may be positioned in the peripheral circuit region PAR of the cell structure CS. The plurality of contact wiring lines CL may include in the second direction Y which is the same as the extension direction of the bit lines BL. The plurality of contact wiring lines CL may be positioned in the peripheral circuit region PAR so as to be spaced apart from each other in the first direction X.

In the embodiment, the plurality of contact wiring lines CL may be positioned in the peripheral circuit region PAR positioned on at least one of both sides of the cell array region CAR in the first direction X. For example, some of the plurality of contact wiring lines CL may be positioned in the peripheral circuit region PAR positioned on one side of the cell array region CAR in the first direction X, and the others may be positioned in the peripheral circuit region PAR positioned on the other side of the cell array region CAR in the first direction X.

In the embodiment, each contact wiring line CL may include a first contact wiring layer 162, a second contact wiring layer 164, and a third contact wiring layer 166 sequentially stacked. The contact wiring lines CL may be formed simultaneously with the bit lines BL in the same process step.

Accordingly, the first contact wiring layer 162 may be formed by the same process as that for the polysilicon layer 161 of the bit lines BL, and the second contact wiring layer 164 may be formed by the same process as that for the first metal layer 163 of the bit lines BL, and the third contact wiring layer 166 may be formed by the same process as that for the second metal layer 165.

Accordingly, the first contact wiring layer 162 may contain the same material as that of the polysilicon layer 161 of the bit lines BL, and the second contact wiring layer 164 may contain the same material as that of the first metal layer 163, and the third contact wiring layer 166 may contain the same material as that of the second metal layer 165. However, this is an example, and the contact wiring lines CL may be formed separately from the bit lines BL in a separate process step, and at least one of the number of layers and material which constitute contact wiring line CL may be variously changed.

The semiconductor device according to the embodiment may further include a shield capping pattern 179 which is positioned on the shield pattern SP, a first cell insulating layer 177 which is positioned between the spacer insulating layer 175 and the second bonding insulating layer 216, a second cell insulating layer 173 which is positioned on the spacer insulating layer 175, the contact wiring line capping layer 168 which is positioned between the plurality of contact wiring lines CL and the spacer insulating layer 175, and an element isolation layer STI which is positioned on the second cell insulating layer 173.

The shield capping pattern 179 may be positioned between the shield pattern SP and the second bonding insulating layer 216 so as to cover the shield pattern SP.

The first cell insulating layer 177 may be positioned on the second bonding insulating layer 216. The upper surface of the first cell insulating layer 177 may be in contact with the spacer insulating layer 175, and a side surface of the first cell insulating layer 177 may be in contact with an end of the shield pattern SP and an end of the shield capping pattern 179.

The second cell insulating layer 173 may be positioned on the spacer insulating layer 175.

As shown in FIG. 4, the second cell insulating layer 173 may be in contact with a side surface of a contact wiring line CL. However, this is an example, and the second cell insulating layer 173 may be positioned apart from a side surface of a contact wiring line CL.

Further, as shown in FIG. 5, the second cell insulating layer 173 may be in contact with an end of a bit line BL and cover the end of the bit line BL. However, this is an example, and the second cell insulating layer 173 may be positioned apart from an end of a bit line BL.

The contact wiring line capping layer 168 may be positioned on the plurality of contact wiring lines CL. The contact wiring line capping layer 168 may be positioned between the spacer insulating layer 175 and the plurality of contact wiring lines CL.

The contact wiring line capping layer 168 may entirely cover the plurality of contact wiring lines CL. The contact wiring line capping layer 168 may cover the lower surfaces and side surfaces of the contact wiring lines CL. The contact wiring line capping layer 168 may fill the space between the plurality of contact wiring lines CL positioned apart from each other.

The element isolation layer STI may be positioned on the second cell insulating layer 173. A portion of the element isolation layer STI may overlap a bit line BL in a third direction Z which is a vertical direction.

The shield capping pattern 179, the first cell insulating layer 177, the second cell insulating layer 173, and the element isolation layer STI may contain at least one of silicon oxide, silicon nitride, silicon oxynitride, and low-dielectric constant materials. For example, the shield capping pattern 179 may contain silicon nitride, and the first cell insulating layer 177, the second cell insulating layer 173, and the element isolation layer STI may contain silicon oxide. However, this is an example, and the material which is contained in each of the shield capping pattern 179, the first cell insulating layer 177, the second cell insulating layer 173, and the element isolation layer STI may be variously changed.

The contact wiring line capping layer 168 may be formed simultaneously with the bit line capping layer 167 in the same process step, and contain the same material as that of the bit line capping layer 167. However, this is an example, and the bit line capping layer 167 and the contact wiring line capping layer 168 may be formed separately in separate process steps, and contain different materials.

The plurality of active patterns AP1 and AP2 may include a plurality of first active patterns AP1 and a plurality of second active patterns AP2 which are positioned apart from each other in the first direction X. The plurality of first active patterns AP1 and the plurality of second active patterns AP2 may be positioned alternately in the second direction Y on the bit lines BL.

The first and second active patterns AP1 and AP2 may be arranged two-dimensionally on a plane along the first direction X and the second direction Y. In other words, the first active patterns AP1 and the second active patterns AP2 may be positioned so as to be spaced apart from and face each other in the second direction Y, respectively.

In the embodiment, each of the first active patterns AP1 and the second active patterns AP2 may include a monocrystalline semiconductor material. For example, each of the first active patterns AP1 and the second active patterns AP2 may include monocrystalline silicon. However, the present disclosure is not limited thereto, and the materials which are contained in the first and second active patterns AP1 and AP2 may be variously changed. For example, the first and second active patterns AP1 and AP2 may contain at least one of polycrystalline semiconductors, oxide semiconductors, and two-dimensional materials. For example, a polycrystalline semiconductor may be polysilicon. As another example, an oxide semiconductor may be indium gallium zinc oxide (IGZO). As a further example, a two-dimensional material may be MoS₂, WS₂, MoSe₂, or WSe₂.

Each of the first active patterns AP1 and the second active patterns AP2 may have a length in the first direction X, have a width in the second direction Y, and have a height in the third direction Z. Each of the first active patterns AP1 and the second active patterns AP2 may include a first surface and a second surface facing each other in the third direction Z.

Here, the first surface may refer to the surface adjacent to a bit line BL, and the second surface may refer to the surface adjacent to a cell capacitor DSP to be described below. In other words, the first surfaces of the active patterns AP1 and AP2 may correspond to the lower surfaces, and the second surfaces may correspond to the upper surfaces.

The first surface and second surface of each of the first active patterns AP1 and the second active patterns AP2 may have substantially the same width. Further, the width of the first active patterns AP1 may be substantially the same as the width of the second active patterns AP2. However, the present disclosure is not limited thereto, and in some embodiments, the first surface and second surface of each of the first active patterns AP1 and the second active patterns AP2 may have different widths. For example, the width of the second surface of each of the first active patterns AP1 and the second active patterns AP2 may be larger than the width of the first surface.

A detailed description of the first and second active patterns AP1 and AP2 will be made below with reference to FIG. 7.

The semiconductor device according to the embodiment may include a plurality of back gate electrodes BG which extends in a direction different from that of the bit lines BL, between the first active patterns AP1 and the second active patterns AP2.

The plurality of back gate electrodes BG may be positioned between the first active patterns AP1 and the second active patterns AP2 adjacent to each other in the second direction Y, and extend in the first direction X across the bit lines BL. In other words, the plurality of back gate electrodes BG may extend across the bit lines BL in a direction different from the extension direction of the bit lines.

The plurality of back gate electrodes BG may be positioned on the bit lines BL and the shield pattern SP. On one side of a back gate electrode BG in the second direction Y, a first active pattern AP1 may be positioned, and on the other side of the back gate electrode BG in the second direction Y, a second active pattern AP2 may be positioned.

The thickness of the back gate electrodes BG in the third direction Z may be smaller than the thicknesses of the first and second active patterns AP1 and AP2 in the third direction Z. However, this is an example, and the relationship between the thickness of the back gate electrodes BG in the third direction Z and the thicknesses of the first and second active patterns AP1 and AP2 in the third direction Z may be variously changed.

Further, a back gate electrode BG may be positioned between a pair of first word line WL1 and second word line WL2 adjacent in the second direction Y. For example, a first active pattern AP1 may be positioned between a first word line WL1 to be described below and a back gate electrode BG, and a second active pattern AP2 may be positioned between a second word line WL2 to be described below and the back gate electrode BG. However, this is an example, and the arrangement relationship of the first and second active patterns AP1 and AP2, the first and second word lines WL1 and WL2 to be described below, and the back gate electrode BG is not limited thereto, and may be variously changed.

The back gate electrode BG may contain a conductive material. For example, the back gate electrode BG may contain at least one of doped polysilicon, conductive metal nitrides, conductive metal silicon nitrides, metal carbonitrides, conductive metal silicides, conductive metal oxides, two-dimensional materials, and metals. However, this is an example, and the conductive material may be variously changed.

During the operation of the semiconductor device, the back gate electrode BG may receive a negative voltage and raise the threshold voltage of a vertical channel transistor. In other words, as the vertical channel transistor is scaled down, the threshold voltage may decrease, whereby the leakage current characteristic may be prevented from being deteriorated.

The semiconductor device according to the embodiment may further include a first back gate insulating pattern 111 and a second back gate insulating pattern 117.

The first back gate insulating pattern 111 and the second back gate insulating pattern 117 may be positioned between the first and second active patterns AP1 and AP2 adjacent to each other in the second direction Y. The first back gate insulating pattern 111 and the second back gate insulating pattern 117 may extend in the first direction X so as to be parallel with the back gate electrodes BG.

The first back gate insulating pattern 111 may be in contact with the first and second active patterns AP1 and AP2. The first back gate insulating pattern 111 may extend in the third direction Z along the side surfaces of each of the first and second active patterns AP1 and AP2 facing each other in the second direction Y.

Each back gate electrode BG may include a first surface and a second surface opposing each other in the third direction Z. Here, the first surface of each back gate electrode BG may refer to the surface facing a bit line BL and the shield pattern SP, and the second surface of each back gate electrode BG may refer to the surface facing a first shield gate SG1 to be described below. In other words, the first surface of each back gate electrode BG may correspond to the lower surface of the back gate electrode BG, and the second surface may correspond to the upper surface of the back gate electrode BG.

The first back gate insulating pattern 111 may extend along both side surfaces of a back gate electrode BG, and the second back gate insulating pattern 117 may be positioned between the first surface of the back gate electrode BG and a bit line BL.

The first back gate insulating pattern 111 and the second back gate insulating pattern 117 may contain insulating materials. Each of the first back gate insulating pattern 111 and the second back gate insulating pattern 117 may contain at least one of silicon oxide, silicon oxynitride, and silicon nitride. However, the materials which are contained in the first back gate insulating pattern 111 and the second back gate insulating pattern 117 are not limited thereto, and may be variously changed.

The plurality of word lines WL1 and WL2 may be positioned on the bit lines BL and the shield pattern SP. The plurality of word lines WL1 and WL2 may include a plurality of first word lines WL1 and a plurality of second word lines WL2 which extend in the first direction X intersecting the second direction Y which is the extension direction of the bit lines BL. The plurality of first word lines WL1 and second word lines WL2 may be positioned apart from each other in the second direction Y.

The plurality of first word lines WL1 and the plurality of second word lines WL2 may overlap a bit line BL and the shield pattern SP in the third direction Z. The plurality of first word lines WL1 and second word lines WL2 may extend in the third direction Z that intersects the first direction X and the second direction Y. In other words, the first word lines WL1 and the second word lines WL2 may be positioned between the bit lines BL and a second shield gate SG2 to be described below, and extend in the third direction Z. A first active pattern AP1 and a second active pattern AP2 may be positioned between a first word line WL1 and a second word line WL2 adjacent in the second direction Y.

Although it is shown in the drawings that in the embodiment, the first and second word lines WL1 and WL2 have a rectangular shape in a cross-sectional view, the cross-sectional shape of the first and second word lines WL1 and WL2 is not limited thereto, and may be variously changed. For example, each of the first and second word lines WL1 and WL2 may have an L shape in a cross-sectional view.

Each of the first and second word lines WL1 and WL2 may include a first surface and a second surface opposing each other in the third direction Z. Here, the first surface of each of the first and second word lines WL1 and WL2 may refer to the surface facing the bit line BL and the shield pattern SP, and the second surface may refer to the surface facing the second shield gate SG2 to be described below. In other words, the first surface of each of the first and second word lines WL1 and WL2 may correspond to the lower surface, and the second surface may correspond to the upper surface.

The first and second word lines WL1 and WL2 may contain a conductive material. For example, the first and second word lines WL1 and WL2 may contain at least one of doped polysilicon, conductive metal nitrides, conductive metal silicon nitrides, metal carbonitrides, conductive metal silicides, conductive metal oxides, two-dimensional materials, and metals. However, the conductive material is not limited thereto.

The semiconductor device according to the embodiment may further include a gate insulating pattern GOX that is positioned on the side surfaces of the word lines WL1 and WL2, a gate isolation pattern 141 that is positioned between the word lines WL1 and WL2, and a gate capping pattern 147 that is positioned on the first surfaces of the word lines WL1 and WL2.

The gate insulating pattern GOX may be in contact with the first and second active patterns AP1 and AP2. The gate insulating pattern GOX may extend in the third direction Z along the side surfaces of the first and second active patterns AP1 and AP2 facing each other in the second direction Y.

The gate isolation pattern 141 may be positioned between the first and second word lines WL1 and WL2 spaced apart in the second direction Y. The gate isolation pattern 141 may be positioned between the gate capping pattern 147 and a second shield capping pattern 145 to be described below.

The gate isolation pattern 141 may be in contact with the first and second word lines WL1 and WL2. The first and second word lines WL1 and WL2 may be isolated and insulated by the gate isolation pattern 141. The gate isolation pattern 141 may extend in the third direction Z between the first and second word lines WL1 and WL2.

Specifically, the gate isolation pattern 141 may include a first surface and a second surface opposing each other in the third direction Z. The first surface of the gate isolation pattern 141 may refer to the surface facing the gate capping pattern 147, and the second surface may refer to the surface facing the second shield capping pattern 145. In other words, the first surface of the gate isolation pattern 141 may correspond to the lower surface, and the second surface may correspond to the upper surface.

The first surface of the gate isolation pattern 141 and the side surfaces adjacent thereto may be covered by the gate capping pattern 147, and the second surface and the side surfaces adjacent thereto may be covered by the second shield capping pattern 145.

The gate capping pattern 147 may be positioned on the first surfaces of the word lines WL1 and WL2. The gate capping pattern 147 may cover the first surfaces of the word lines WL1 and WL2.

The gate insulating pattern GOX may contain silicon oxide, silicon oxynitride, a high-dielectric constant material having a dielectric constant higher than that of silicon oxide, or a combination thereof. For example, the high-dielectric constant material may contain any one of HfO₂, HfSiO, HfSiON, HfTaO, HfTiO, HfZrO, ZrO₂, Al₂O₃, or combinations thereof, but is not limited thereto.

The gate isolation pattern 141 and the gate capping pattern 147 may contain any one of silicon oxide, silicon nitride, or combinations thereof. For example, the gate isolation pattern 141 may contain silicon oxide, and the gate capping pattern 147 may contain silicon nitride. However, the present disclosure is not limited thereto.

The plurality of shield gates SG may overlap at least some of the first and second active patterns AP1 and AP2 in the second direction Y which is a horizontal direction. The plurality of shield gates SG may be positioned at a level between the word lines WL1 and WL2 and the cell capacitor DSP and/or between the back gate electrode BG and the cell capacitor DSP.

More specifically, the plurality of shield gates SG may be positioned at a level between the upper surfaces of the word lines WL1 and WL2 and the lower surface of the buried contact BC to be described below and/or between the upper surface of the back gate electrode BG and the lower surface of the buried contact BC.

In the embodiment, the plurality of shield gates SG may include a plurality of first shield gates SG1 which is positioned on the back gate electrode BG, and the second shield gate SG2 which is positioned on the word lines WL1 and WL2.

The plurality of first shield gates SG1 may be positioned so as to overlap the plurality of back gate electrodes BG in the third direction Z, and a plurality of second shield gates SG2 may be positioned so as to overlap each of the plurality of word lines WL1 and WL2 in the third direction Z.

The first shield gates SG1 may extend in the third direction Z on the back gate electrode BG, and the second shield gates SG2 may extend in the third direction Z on the word lines WL1 and WL2.

The plurality of shield gates SG may be positioned between a first active pattern AP1 and a second active pattern AP2 adjacent to each other in the second direction Y. The thickness of the plurality of shield gates SG in the third direction Z may be smaller than the thickness of the first and second active patterns AP1 and AP2 in the third direction Z. Accordingly, each shield gate SG may be positioned so as to overlap some portions of the first and second active patterns AP1 and AP2 in the second direction Y.

A detailed description of the arrangement relationship of the first and second active patterns AP1 and AP2 and the shield gate SG will be made below with reference to FIG. 7.

In the embodiment, in a plan view, the first shield gates SG1 may have substantially the same shape as that of the back gate electrodes BG, and the second shield gates SG2 may have substantially the same shape as that of the first word lines WL1 and the second word lines WL2.

Specifically, as shown in FIGS. 2 and 3, in the embodiment, a first shield gate SG1 which overlaps a back gate electrode BG in the third direction Z may extend in the first direction X and have a rectangular shape in a plan view, similar to the back gate electrode BG.

Although it is shown in the drawings that in a plan view, a back gate electrode BG and a first shield gate SG1 entirely overlap in the third direction Z in the embodiment, but the present disclosure is not limited thereto. For example, unlike in FIG. 2, the back gate electrode BG and the first shield gate SG1 may have different shapes in a plan view or have different areas, such that the back gate electrode BG and the first shield gate SG1 only partially overlap in the third direction Z.

As shown in FIGS. 2 and 3, the first and second word lines WL1 and WL2 may include gate line portions WL1_B and WL2_B that extend in the first direction X, and gate protrusion portions WL1_P and WL2_P that extend in the second direction Y from the gate line portions WL1_B and WL2_B.

Specifically, each first word line WL1 may include a first gate line portion WL1_B that extends in the first direction X, and a first gate protrusion portion WL1_P that extends in the second direction Y from the first gate line portion WL1_B and is positioned between first active patterns AP1 adjacent to each other in the first direction X.

Each second word line WL2 may include a second gate line portion WL2_B that extends in the first direction X, and a second gate protrusion portion WL2_P that extends in the second direction Y from the second gate line portion WL2_B and is positioned between second active patterns AP2 adjacent to each other in the first direction X.

Accordingly, each of the first and second active patterns AP1 and AP2 may be surrounded by the gate line portions WL1_B and WL2_B and gate protrusion portions WL1_P and WL2_P of the first and second word lines WL1 and WL2 in a plan view.

In the embodiment, each second shield gate SG2 may include a shield line portion SG2_B that extends in the first direction X, and a shield protrusion portion SG2_P that extends in the second direction Y from the shield line portion SG2_B and is positioned between first active patterns AP1 adjacent to each other in the first direction X.

The shield line portion SG2_B of the second shield gate SG2 may have substantially the same planar shape as that of the gate line portions WL1_B and WL2_B of the above-mentioned individual first and second word lines WL1 and WL2, and overlap them in the third direction Z. Further, the shield protrusion portion SG2_P of the second shield gate SG2 may have substantially the same planar shape as that of the gate protrusion portions WL1_P and WL2_P of the above-mentioned individual first and second word lines WL1 and WL2, and overlap them in the third direction Z.

Accordingly, each of the first and second active patterns AP1 and AP2 may be surrounded by the shield line portion SG2_B and shield protrusion portion SG2_P of a second shield gate SG2 in a plan view.

As shown in FIGS. 2 and 3, the word lines WL1 and WL2 and the second shield gate SG2 may entirely overlap in the third direction Z in a plan view; however, the present disclosure is not limited thereto. For example, unlike shown in FIGS. 2 and 3, the word lines WL1 and WL2 and the second shield gate SG2 may have different shapes in a plan view or have different areas, such that they partially overlap in the third direction Z.

In the embodiment, the shield gate SG may contain a conductive material. For example, the first shield gate SG1 may contain the same conductive material as that of the back gate electrode BG, and the second shield gate SG2 may contain the same conductive material as that of the word lines WL1 and WL2. However, the conductive material which is contained in the shield gate SG is not limited thereto, and may be variously changed. For example, the first shield gate SG1 may contain a conductive material different from that of the back gate electrode BG, and the second shield gate SG2 may contain a conductive material different from that of the word lines WL1 and WL2. As another example, the first shield gate SG1 and the second shield gate SG2 may contain the same material, and the first and second shield gates SG1 and SG2 may contain a conductive material different from those of the word lines WL1 and WL2 and the back gate electrode BG.

Further, in some embodiments, the first shield gate SG1 may contain a conductive material having a work function different from that of the back gate electrode BG, and the second shield gate SG2 may contain a conductive material having a work function different from that of the word lines WL1 and WL2. For example, each of the first shield gate SG1 and the second shield gate SG2 may contain a higher work function than the word lines WL1 and WL2 and the back gate electrode BG.

As a more specific example, the first shield gate SG1 and the second shield gate SG2 may contain one of aluminum (Al), copper (Cu), titanium (Ti), tantalum (Ta), tungsten (W), molybdenum (Mo), TaN, NiSi, CoSi, TiN, WN, TiAl, TiAlC, TiAlN, TaCN, TaC, or combinations thereof.

The semiconductor device according to the embodiment may further include a first shield isolation pattern 113 that is positioned between the back gate electrode BG and the first shield gate SG1, a first shield capping pattern 115 that is positioned on the first shield gate SG1, a second shield isolation pattern 143 that is positioned between the word lines WL1 and WL2 and the second shield gate SG2, and a second shield capping pattern 145 that is positioned on the second shield gate SG2.

The first shield isolation pattern 113 may be positioned between the back gate electrode BG and the first shield gate SG1, and isolate and insulate them. The first shield capping pattern 115 may be positioned on the first shield gate SG1, and cover the first shield gate SG1. The first shield capping pattern 115 may be positioned between the first shield gate SG1 and a contact interlayer insulating layer 271 to be described below.

Both side surfaces of each of the first shield gate SG1, the first shield isolation pattern 113, and the first shield capping pattern 115 may be surrounded by the first back gate insulating pattern 111.

The second shield isolation pattern 143 may be positioned between the word lines WL1 and WL2 and the second shield gate SG2, and isolate and insulate them. The second shield capping pattern 145 may be positioned on the second shield gate SG2, and cover the second shield gate SG2.

The second shield capping pattern 145 may cover the upper surface of the gate isolation pattern 141 positioned at a higher level than the second shield gate SG2, and both side surfaces adjacent thereto. The second shield capping pattern 145 may be positioned between the second shield gate SG2 and the buried contact BC to be described below and between the gate isolation pattern 141 and the contact interlayer insulating layer 271 to be described below.

Both side surfaces of each of the second shield gate SG2, the second shield isolation pattern 143, and the second shield capping pattern 145 may be surrounded by the gate insulating pattern GOX.

Each of the first shield isolation pattern 113, the first shield capping pattern 115, the second shield isolation pattern 143, and the second shield capping pattern 145 may contain an insulating material. For example, the insulating material may include silicon oxide, silicon nitride, silicon oxynitride, etc., but is not limited thereto, and may be variously changed.

The semiconductor device according to the embodiment may further include a word line contact 241 that is positive the peripheral circuit region PAR of the cell structure CS, a second shield gate contact 243, the bit line contact 245, a first contact via 246 that connects the contact wiring line CL and the back gate electrode BG, and a second contact via 248 that connects the contact wiring line CL and the first shield gate SG1.

In the semiconductor device according to the embodiment, the word lines WL1 and WL2 may extend in the first direction X from the cell array region CAR to the peripheral circuit region PAR. Accordingly, the end portions of the word lines WL1 and WL2 may be positioned in the peripheral circuit region PAR, and the word line contact 241 may be connected around the end portions of the word lines WL1 and WL2 positioned in the peripheral circuit region PAR.

Further, in the embodiment, the second shield gate SG2 may extend in the first direction X from the cell array region CAR to the peripheral circuit region PAR. Accordingly, an end portion of the second shield gate SG2 may be positioned in the peripheral circuit region PAR, and the second shield gate contact 243 may be connected around the end portion of the second shield gate SG2 positioned in the peripheral circuit region PAR.

As shown in FIG. 1, in the embodiment, a plurality of word line contacts 241 and a plurality of second shield gate contacts 243 may be positioned in the peripheral circuit region PAR positioned on both sides of the cell array region CAR in the first direction X.

The plurality of word line contacts 241 and the plurality of second shield gate contacts 243 may be arranged so as to be spaced apart from each other in the first direction X in a plan view. For example, a word line contact 241 and a second shield gate contact 243 may be arranged side by side in the first direction X.

The plurality of word line contacts 241 and the plurality of second shield gate contacts 243 may be arranged in a zigzag form along the second direction Y. For example, each of the word line contacts 241 and the second shield gate contacts 243 which are positioned in the first row may be positioned so as to be spaced apart from the word line contacts 241 and the second shield gate contacts 243 which are positioned in the second row, in a diagonal direction intersecting the first direction X and the second direction Y. However, this is an example, and the arrangement of the plurality of word line contacts 241 and the plurality of second shield gate contacts 243 in a plan view may be variously changed.

As shown in FIG. 4, in the embodiment, the extension length of a second word line WL2 in the second direction Y may be different from the extension length of a second shield gate SG2 in the second direction Y.

Accordingly, the second word line WL2 and the second shield gate SG2 may have a step, and be stacked in a stepped shape in a cross-sectional view. In a cross-sectional view, an end portion of the second shield gate SG2 may be positioned so as to protrude in the first direction X from an end portion of the second word line WL2. The second word line WL2 and the second shield gate SG2 may be stacked in the stepped shape in a cross-sectional view, such that a portion of the second shield gate SG2 which is positioned on the second word line WL2 does not overlap the second word line WL2 in the third direction Z.

As shown in FIG. 4, an end of the second shield isolation pattern 143 which is positioned between the second word line WL2 and the second shield gate SG2 may be aligned with an end of the second word line WL2 substantially at the same boundary. In other words, the second shield isolation pattern 143 which is positioned between the second word line WL2 and the second shield gate SG2 may expose a portion of the second shield gate SG2 positioned so as to protrude from an end of the second word line WL2 to one side in first direction X.

Further, the second word line WL2 and the second shield gate SG2 sequentially stacked in the stepped shape in a cross-sectional view may be covered by the gate capping pattern 147. In other words, the gate capping pattern 147 may cover an end of the second word line WL2, an end of the second shield isolation pattern 143, the portion of the second shield gate SG2 experienced by the second shield isolation pattern 143, and an end of the second shield gate SG2.

As the second word line WL2 and the second shield gate SG2 have a stepped shape in a cross-sectional view, the word line contact 241 and the second shield gate contact 243 may be connected to the second word line WL2 and the second shield gate SG2, respectively, corresponding to the stepped shape.

The word line contact 241 may be connected to the lower surface of the second word line WL2, and the second shield gate contact 243 may be connected around the end portion of the second shield gate SG2 which does not overlap the second word line WL2 in the third direction Z.

One ends of the word line contact 241 and the second shield gate contact 243 may be connected to the second word line WL2 and the second shield gate SG2, respectively, and the other ends of them may be connected to the cell connection wiring lines 232. However, the connection relationship of the second word line WL2 and the word line contact 241 and/or the comparison result of the second shield gate SG2 and the second shield gate contact 243 are not limited thereto, and may be variously changed.

For example, unlike shown in FIG. 4, the second word line WL2 and the second shield gate SG2 may extend so as to have substantially the same length in the first direction X such that the ends of the second word line WL2 and the second shield gate SG2 are aligned substantially at the same boundary, and the word line contact 241 may be connected to the lower surface of the second word line WL2, and the second shield gate contact 243 may pass through the second word line WL2 and the second shield isolation pattern 143 and be connected to the second shield gate SG2.

The word line contact 241 and the second shield gate contact 243 connected to the cell connection wiring lines 232 may be connected to the peripheral circuit wiring lines PCL1 and PCL2 and/or the peripheral circuit PC positioned in the peripheral circuit structure PS through the cell connection wiring lines 232. However, the connection relationship between the second word line WL2 and/or the second shield gate SG2 and the peripheral circuit structure PS is not limited thereto, and may be variously changed.

In the embodiment, the second word line WL2 and the second shield gate SG2 may receive the same voltage through the word line contact 241 and the second shield gate contact 243, respectively. For example, the word line contact 241 and the second shield gate contact 243 may be connected to one driver such that the same voltage may be applied to the second word line WL2 and the second shield gate SG2. However, the present disclosure is not limited thereto.

For example, the word line contact 241 and the second shield gate contact 243 may be connected to one driver, and different voltages may be applied to the second word line WL2 and the second shield gate SG2, respectively, by the operation and/or configuration of the driver.

When the same voltage is applied to the second word line WL2 and the second shield gate SG2, since the second shield gate SG2 contains a conductive material having a higher work function than the second word line WL2 as described above, the threshold voltage of the memory transistor MT may be adjusted to improve the electrical characteristics of the memory transistor MT. In other words, since the second shield gate SG2 contains a material having a higher work function than the second word line WL2, the second shield gate SG2 may serve as a gate electrode for the memory transistor MT, together with the second word line WL2, to adjust the threshold voltage of the memory transistor MT.

Regarding the second word line WL2, the stacking relationship and contact relationship with the second shield gate SG2, and the like have been described with reference to FIG. 4. The description of them may be substantially equally applied to the first word line WL1 and the second shield gate SG2, and thus, a detailed description thereof will not be made.

According to the embodiment, as shown in FIG. 5, the extension length of the bit line BL in the second direction Y may be different from the extension length of the shield pattern SP in the second direction Y. Accordingly, the bit line BL may include a portion which does not overlap the shield pattern SP in the third direction Z which is the vertical direction.

The bit line contact 245 may be connected around the end portion of the bit line BL which does not overlap the shield pattern SP in the third direction Z. In other words, the bit line contact 245 may be connected to the second metal layer 165 of the bit line BL which does not overlap the shield pattern SP in the third direction Z. One end of the bit line contact 245 may be connected to the second metal layer 165 of the bit line BL, and the other end may be connected to the cell connection wiring line 232.

Accordingly, the bit line contact 245 connected to the cell connection wiring line 232 may be connected to the peripheral circuit wiring lines PCL1 and PCL2 and/or the peripheral circuit PC, which are positioned in the peripheral circuit structure PS, through the first bonding pad 221. However, the connection relationship of the bit line BL and the peripheral circuit structure PS is not limited thereto, and may be variously changed.

In the semiconductor device according to the embodiment, the back gate electrode BG and the first shield gate SG1 may extend in the first direction X from the cell array region CAR to the peripheral circuit region PAR.

Accordingly, the back gate electrode BG which is positioned in the peripheral circuit region PAR may be connected to the first contact via 246 connected to the contact wiring line CL, and the first shield gate SG1 which is positioned in the peripheral circuit region PAR may be connected to the second contact via 248 connected to the contact wiring line CL.

As shown in FIG. 6, the back gate electrode BG, the first shield gate SG1, and the end of the first shield isolation pattern 113 which is positioned between them may be arranged substantially at the same boundary. In other words, the first shield gate SG1 and the back gate electrode BG may entirely overlap in the third direction Z.

The first contact via 246 may pass through the first contact wiring layer 162 of the contact wiring line CL and the second back gate insulating pattern 117, thereby connecting any one of the plurality of contact wiring lines CL and the back gate electrode BG.

One end of the first contact via 246 may be connected to the second contact wiring layer 164 of the contact wiring line CL, and the other end may be connected to the lower surface of the back gate electrode BG. For example, the first contact via 246 may be formed simultaneously with the second contact wiring layer 164 of the contact wiring line CL in the same process step, and contain the same material as that of the second contact wiring layer 164. However, the present disclosure is not limited thereto, and the first contact via 246 may be formed simultaneously with the first contact wiring layer 162 or the third contact wiring layer 166 in the same process step, and contain the same material as that of the first contact wiring layer or the third contact wiring layer.

The second contact via 248 may pass through the first contact wiring layer 162, the second back gate insulating pattern 117, the back gate electrode BG, and the first shield isolation pattern 113, thereby connecting another one of the plurality of contact wiring lines CL and the first shield gate SG1.

One end of the second contact via 248 may be connected to the second contact wiring layer 164 of the contact wiring line CL, and the other end may be connected to the lower surface of the first shield gate SG1 which is in contact with the first shield isolation pattern 113.

In the embodiment, the second contact via 248 may include a contact conduction pattern 248a, and a contact insulating pattern 248b which surrounds the contact conduction pattern 248a.

Specifically, the contact conduction pattern 248 a of the second contact via 248 may pass through the first contact wiring layer 162, the second back gate insulating pattern 117, the back gate electrode BG, and the first shield isolation pattern 113.

The contact conduction pattern 248a may be formed simultaneously with the second contact wiring layer 164 of the contact wiring line CL in the same process step, and contain the same material as that of the second contact wiring layer 164. However, the present disclosure is not limited thereto, and the contact conduction pattern 248a may be formed simultaneously with the first contact wiring layer 162 or the third contact wiring layer 166 in the same process step, and contain the same material as that of the first contact wiring layer 162 or the third contact wiring layer 166.

The contact insulating pattern 248 b of the second contact via 248 may surround the side surfaces of the contact conduction pattern 248a. The contact insulating pattern 248b may insulate and isolate the contact conduction pattern 248a from the back gate electrode BG.

The contact insulating pattern 248b may contain an insulating material. For example, the contact insulating pattern 248b may contain at least one of silicon oxides or silicon nitrides. However, the contact insulating pattern is not limited thereto.

The connection relationship of the first contact via 246 and the back gate electrode BG and/or the connection relationship of the second contact via 248 and the first shield gate SG1 are not limited to those shown in FIG. 6, and may be variously changed. For example, like the second word line WL2 and the second shield gate SG2 described above with reference to FIG. 4, the back gate electrode BG and the first shield gate SG1 may have different extension lengths in the first direction X, thereby having a stepped shape in a cross-sectional view.

Accordingly, the first contact via 246 and the second contact via 248 may be connected to the back gate electrode BG and the first shield gate SG1 having the stepped shape, respectively. When the back gate electrode BG and the first shield gate SG1 have a stepped shape in a cross-sectional view, the contact insulating pattern 248b of the second contact via 248 may be omitted.

The semiconductor device according to the embodiment may further include a back gate contact 242 that connects the cell connection wiring line 232 and the contact wiring line CL connected to the first contact via 246, and a first shield gate contact 244 that connects the cell connection wiring line 232 and the contact wiring line CL connected to the second contact via 248. For example, as shown in FIG. 1, the back gate contact 242 and the first shield gate contact 244 may be connected to the end portions of the contact wiring lines CL which are positioned in the peripheral circuit region PAR. However, the present disclosure is not limited thereto.

Accordingly, the first shield gate contact 244 and the back gate contact 242 connected to the cell connection wiring line 232 may be connected to the peripheral circuit wiring lines PCL1 and PCL2 and/or the peripheral circuit PC positioned in the peripheral circuit structure PS.

In the embodiment, the same voltage may be applied to each of the back gate electrode BG and the first shield gate SG1. For example, the back gate contact 242 and the first shield gate contact 244 described above may be connected to one driver, and the same voltage may be applied to each of the back gate electrode BG and the first shield gate SG1. However, the present disclosure is not limited thereto. For example, the back gate contact 242 and the first shield gate contact 244 may be connected to one driver, and different voltages may be applied to the back gate electrode BG and the first shield gate SG1, respectively, by the operation and/or configuration of the driver.

When the same voltage is applied to the back gate electrode BG and the first shield gate SG1, since the first shield gate SG1 contains a conductive material having a higher work function than the back gate electrode BG as described above, the threshold voltage of the memory transistor MT may be adjusted to improve the electrical characteristics of the memory transistor MT.

Further, in the embodiment, different voltages may be applied to the word lines WL1 and WL2 and the back gate electrode BG through the word line contact 241 and the back gate contact 242, respectively. However, the present disclosure is not limited thereto, and in some embodiments, the same voltage may be applied to each of the word lines WL1 and WL2 and the back gate electrode BG.

The semiconductor device according to the embodiment may further include the contact interlayer insulating layer 271, a pad isolation insulating layer 273, and a contact etch stop layer 275 sequentially stacked on the active patterns AP1 and AP2.

The contact interlayer insulating layer 271 may be positioned on the active patterns AP1 and AP2. The contact interlayer insulating layer 271 may cover the first back gate insulating pattern 111, the first and second shield capping patterns 115 and 145, and the element isolation layer STI.

The contact interlayer insulating layer 271, the pad isolation insulating layer 273, and the contact etch stop layer 275 may contain silicon oxide, silicon nitride, or a combination thereof. For example, the contact interlayer insulating layer 271 may contain silicon oxide, and the pad isolation insulating layer 273 and the contact etch stop layer 275 may contain silicon nitride. However, the present disclosure is not limited thereto.

In the cell array region CAR of the cell structure CS, the buried contact BC, the landing pad LP, and the cell capacitor DSP may be sequentially stacked.

The semiconductor device according to the embodiment may include a plurality of buried contacts BC. The plurality of buried contacts BC may pass through the contact interlayer insulating layer 271. The plurality of buried contacts BC may be connected to the first and second active patterns AP1 and AP2, respectively. Buried contacts BC adjacent to each other may be isolated and insulated from each other by the contact interlayer insulating layer 271.

The plurality of buried contacts BC may be arranged in a matrix pattern along the first direction X and the second direction Y on a plane. In FIG. 1, it is shown that each buried contact BC has a circular shape on a plane; however, the present disclosure is not limited thereto, and each buried contact BC may have various shapes such as an oval shape, a rectangular shape, a square shape, a rhombic shape, and a hexagonal shape in a plan view.

The buried contact BC may contain a conductive material. For example, the conductive material may contain at least one of doped polysilicon, conductive metal nitrides, conductive metal silicon nitrides, metal carbonitrides, conductive metal silicides, conductive metal oxides, two-dimensional materials, and metals.

The semiconductor device according to the embodiment may include a plurality of landing pads LP. The plurality of landing pads LP may be positioned on the plurality of buried contacts BC, respectively.

The plurality of landing pads LP may be arranged in a matrix form along the first direction X and the second direction Y in a plan view. In FIG. 1, it is shown that each landing pad LP has a circular shape on a plane; however, the present disclosure is not limited thereto, and each landing pad LP may have various shapes such as an oval shape, a rectangular shape, a square shape, a rhombic shape, and a hexagonal shape in a plan view.

Between the landing pads LP, pad isolation insulating layers 273 may be positioned. The upper surface of the landing pad LP may be positioned substantially at the same level as that of the upper surface of the pad isolation insulating layer 273.

The landing pad LP may contain a conductive material. The conductive material may contain, for example, at least one of doped polysilicon, conductive metal nitrides, conductive metal silicon nitrides, metal carbonitrides, conductive metal silicides, conductive metal oxides, two-dimensional materials, and metals.

The semiconductor device according to the embodiment may include a plurality of cell capacitors DSP. The plurality of cell capacitors DSP may be arranged in a matrix pattern along the first direction X and the second direction Y, as shown in FIG. 1.

The plurality of cell capacitors DSP may be positioned on the plurality of landing pads LP, respectively. The plurality of cell capacitors DSP may entirely or partially overlap the plurality of landing pads LP in the third direction Z, respectively. The plurality of cell capacitors DSP may be connected to the first and second active patterns AP1 and AP2, respectively.

Each cell capacitor DSP may include a first electrode 251, a second electrode 255, and a dielectric film 253 which is positioned between the first electrode 251 and the second electrode 255.

The first electrode 251 may pass through the contact etch stop layer 275 and be connected to the landing pad LP. The first electrode 251 may extend in the third direction Z on the landing pad LP.

The first electrode 251 may contain a metal, a conductive metal nitride, or a combination thereof. For example, the first electrode 251 may include TiN, Ru, TaN, WN, Pt, Ir, or a combination thereof. However, the material which is contained in the first electrode 251 is not limited thereto, and may be variously changed.

The dielectric film 253 may extend so as to conform to the profile of the upper surface and side surfaces of the first electrode 251. In other words, the dielectric film 253 may cover the side surfaces and upper surface of the first electrode 251. A portion of the dielectric film 253 may be positioned on the upper surface of the contact etch stop layer 275. In other words, a portion of the dielectric film 253 may be positioned between the contact etch stop layer 275 and the second electrode 255.

The dielectric film 253 may contain tantalum oxide (Ta₂O₅), aluminum oxide (Al₂O₃), titanium oxide (TiO₂), or a combination thereof. However, the present disclosure is not limited thereto, and the material which is contained in the dielectric film 253 may be variously changed.

The second electrode 255 may be positioned on the dielectric film 253. The second electrode 255 may entirely cover the first electrode 251. In other words, the second electrode 255 may cover the upper surface and side surfaces of the first electrode 251.

The second electrode 255 may contain a metal material such as W, Ti, Ru, SiGe, etc. For example, the second electrode 255 may contain tungsten (W). However, the material which is contained in the second electrode 255 is not limited thereto, and may be variously changed. For example, the second electrode 255 may contain conductive metal nitride, metal silicide, or a combination thereof.

The semiconductor device according to the embodiment may further include a third cell insulating layer 277 and a fourth cell insulating layer 279 sequentially stacked on the contact etch stop layer 275.

Also, the semiconductor device according to the embodiment may further include a first cell wiring contact 261 and a first cell wiring line 262 which are positioned inside the third cell insulating layer 277, and a second cell wiring contact 263 and a second cell wiring line 264 which are positioned inside the fourth cell insulating layer 279.

The third cell insulating layer 277 may entirely cover the cell capacitor DSP. In other words, the third cell insulating layer 277 may cover the upper surface and side surfaces of the cell capacitor DSP.

The cell capacitor DSP may be connected to the first cell wiring line 262 through the first cell wiring contact 261, and the first cell wiring line 262 may be connected to the second cell wiring line 264 through the second cell wiring contact 263.

In the embodiment, the first cell wiring line 262 may be a wiring line to which an external voltage is applied, or a redistribution layer (RDL) connected to a wiring line to which a voltage is applied. At least a portion of the second cell wiring line 264 may correspond to a power line to which an external voltage is applied. However, this is an example, and the functions of the first cell wiring line 262 and the second cell wiring line 264 may be variously changed.

The first cell wiring contact 261, the first cell wiring line 262, the second cell wiring contact 263, and the second cell wiring line 264 may contain any one of metals, such as copper (Cu), aluminum (Al), tungsten (W), titanium (Ti), and tantalum (Ta), or combinations thereof.

Hereinafter, the arrangement relationship of the active patterns AP1 and AP2, the shield gate SG, the word lines WL1 and WL2, and the back gate electrode BG will be described in detail with reference to FIG. 7.

Referring to FIG. 7 together with FIG. 5, each of the first and second active patterns AP1 and AP2 may include a first dopant region SDR1 connected to the bit line BL, a second dopant region SDR2 connected to the cell capacitor DSP, and a channel region CHR that is positioned between the first and second dopant regions SDR1 and SDR2. The second dopant region SDR2 may be connected to the cell capacitor DSP through the buried contact BC and the landing pad LP.

The first and second dopant regions SDR1 and SDR2 are regions inside the first and second active patterns AP1 and AP2, doped with a dopant, and the dopant concentration in the first and second dopant regions SDR1 and SDR2 may be higher than the dopant concentration in the channel region CHR.

The first and second active patterns AP1 and AP2 may be controlled by the first and second word lines WL1 and WL2 to be described below and/or the back gate electrodes BG to be described below during the operation of the semiconductor device. As described above, in the embodiment, when the first and second active patterns AP1 and AP2 contain a monocrystalline semiconductor material, the leakage current characteristic of the semiconductor memory device can be improved.

The first and second dopant regions SDR1 and SDR2 of the active patterns AP1 and AP2 may correspond to the first source/drain electrode and second source/drain electrode of the memory transistor MT, and the channel region CHR may correspond to the channel of the memory transistor MT.

In the embodiment, the thickness of the word lines WL1 and WL2 in the third direction Z may be substantially the same as the thickness of the back gate electrode BG in the third direction Z. In other words, the upper surfaces and lower surfaces of the word lines WL1 and WL2 may be positioned substantially at the same levels as those of the upper surface and lower surface of the back gate electrode BG, respectively. However, the present disclosure is not limited thereto, and either or both of the upper surfaces and lower surfaces of the word lines WL1 and WL2 may be positioned at levels different from those of the upper surface and lower surface of the back gate electrode BG.

Further, in some embodiments, the thickness of the first and second word lines WL1 and WL2 in the third direction Z may be smaller than the thickness of the first and second active patterns AP1 and AP2 in the third direction Z. However, the relationship of the thickness of the word lines WL1 and WL2 in the third direction Z and the thickness of the back gate electrode BG in the third direction Z, the arrangement relationship of the word lines WL1 and WL2 and the back gate electrode BG, and the relationship of the thickness of the word lines WL1 and WL2 in the third direction Z and the thickness of the active patterns AP1 and AP2 in the third direction Z are not limited thereto, and may be variously changed.

In the embodiment, the shield gate SG may overlap at least one second dopant region SDR2 of the active patterns AP1 and AP2 in the second direction Y which is a horizontal direction. For example, the shield gate SG may be positioned so as to overlap the second dopant region SDR2 of each of the active patterns AP1 and AP2 in the second direction Y which is a horizontal direction.

Further, the shield gate SG may be positioned at a higher level than the channel region CHR so as not to overlap the channel region CHR in the second direction Y.

The thickness of the shield gate SG in the third direction Z may be smaller than the thickness of the second dopant region SDR2 in the third direction Z. Accordingly, the shield gate SG may overlap a portion of the second dopant region SDR2 in the second direction Y. In other words, the shield gate SG may overlap the second dopant region SDR2 in a direction intersecting the extension direction of the second dopant region SDR2.

As the shield gate SG is positioned so as to overlap the second dopant regions SDR2 of the active patterns AP1 and AP2 as described above, interference between the second dopant regions SDR2 adjacent to each other can be reduced.

The first shield isolation pattern 113 may include a first surface and a second surface which face each other in the third direction Z and are in contact with the back gate electrode BG and the first shield gate SG1, respectively. The second shield isolation pattern 143 may include a first surface and a second surface which face each other in the third direction Z and are in contact with the word lines WL1 and WL2 and the second shield gate SG2, respectively. Here, the first surface may correspond to the lower surface, and the second surface may correspond to the upper surface.

In the embodiment, the thickness of the first shield isolation pattern 113 in the third direction Z may be substantially the same as the thickness of the second shield isolation pattern 143 in the third direction Z.

Further, the first surface of the first shield isolation pattern 113 may be positioned substantially at the same level as that of the first surface of the second shield isolation pattern 143, and the second surface of the first shield isolation pattern 113 may be positioned substantially at the same level as that of the second surface of the second shield isolation pattern 143. However, the present disclosure is not limited thereto, and the thickness relationship and/or arrangement relationship of the first and second shield isolation patterns 113 and 143 may be variously changed.

In the embodiment, the first surfaces of the first and second shield isolation patterns 113 and 143 may be positioned at a higher level than the channel regions CHR of the active patterns AP1 and AP2. Accordingly, the first and second shield isolation patterns 113 and 143 may not overlap the channel regions CHR in the second direction Y. However, the present disclosure is not limited thereto, and some portions of the first and second shield isolation patterns 113 and 143 may overlap the channel regions CHR in the second direction Y.

The first shield gate SG1 may include a first surface SG1_S1 and a second surface SG1_S2 which face each other in the third direction Z and are in contact with the first shield isolation pattern 113 and the first shield capping pattern 115, respectively.

Both side surfaces (SG1_S1 and SG1_SG2) of the first shield gate SG1 may be in contact with the first back gate insulating pattern 111. In other words, both side surfaces (SG1_S1 and SG1_SG2) of the first shield gate SG1 may face the second dopant regions SDR2 of the active patterns AP1 and AP2 with the first back gate insulating pattern 111 interposed therebetween.

The second shield gate SG2 may include a first surface SG2_S1 and a second surface SG2_S2 which face each other in the third direction Z and are in contact with the second shield isolation pattern 143 and the second shield capping pattern 145, respectively.

The second shield gate SG2 may include a first side surface SG2_S3 and a second side surface SG2_S4 which face each other in the second direction Y.

The first side surface SG2_S3 of the second shield gate SG2 positioned on the first word line WL1 among the plurality of second shield gates SG2 may be in contact with the gate isolation pattern 141, and the second side surface SG2_S4 may be in contact with the gate insulating pattern GOX.

The first side surface SG2_S3 of the second shield gate SG2 positioned on the second word line WL2 among the plurality of second shield gates SG2 may be in contact with the gate insulating pattern GOX, and the second side surface SG2_S4 may be in contact with the gate isolation pattern 141.

In the embodiment, the first surface SG1_S1 of the first shield gate SG1 may be positioned substantially at the same level as that of the second surface SG2_S2 of the second shield gate SG2. The second surface SG1_S2 of the second shield gate SG2 may be positioned substantially at the same level as that of the second surface SG2_S2 of the second shield gate SG2.

The second surface SG1_S2 of the first shield gate SG1 and the second surface SG2_S2 of the second shield gate SG2 may be positioned at a higher level than the upper surface of the gate isolation pattern 141. However, as any one of the present disclosure is not limited thereto, and the thickness of the word lines WL1 and WL2 in the third direction Z, the thickness of the first and second shield isolation patterns 113 and 143 in the third direction Z, and the thickness of the back gate electrode BG in the third direction Z, the arrangement relationship of the first and second shield gates SG1 and SG2 may be variously changed.

The first shield gate SG1 and the back gate electrode BG may have a first width W1, and the second shield gate SG2 and the word lines WL1 and WL2 may have a second width W2.

In the embodiment, the first shield gate SG1 and the back gate electrode BG may have substantially the same first width W1, and the second shield gate SG2 and each of the word lines WL1 and WL2 may have substantially the same second width W2. Here, the first width W1 and the second width W2 may refer to widths in the second direction Y.

In the embodiment, the first width W1 may be larger than the second width W2. In other words, the width of the first shield gate SG1 may be larger than the width of the second shield gates SG2, and the width of the back gate electrode BG may be larger than the width of the word lines WL1 and WL2. However, the present disclosure is not limited thereto, and the first width W1 and the second width W2 may be variously changed. For example, the first width W1 may be substantially the same as the second width W2. In other words, the width of the back gate electrode BG may be substantially the same as the width of each of the word lines WL1 and WL2, and the width of the first shield gate SG1 may be substantially the same as the width of the second shield gate SG2.

According to the semiconductor device according to the embodiment, as the shield gate SG is formed between the dopant regions of the active patterns AP1 and AP2, coupling due to interference between the dopant regions of the active patterns AP1 and AP2 adjacent to each other can be improved.

Further, as a voltage is applied to the shield gate SG, it is possible to increase the amount of current of the memory transistor MT in the on state while reducing gate induced drain leakage which occurs in the memory transistor MT, such that the electrical characteristics of the semiconductor device are improved. Accordingly, it is possible to provide the semiconductor device with improved reliability and productivity.

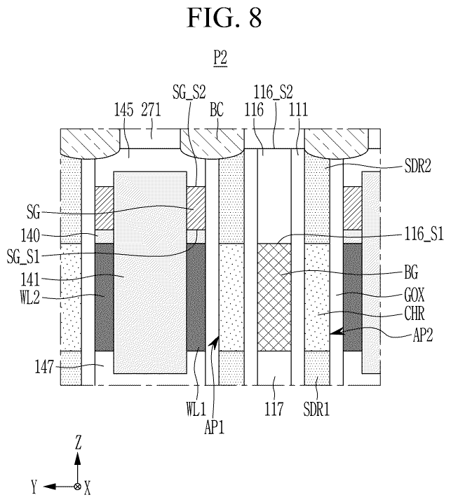

Hereinafter, semiconductor devices according to various embodiments will be described with reference to FIGS. 8 to 24. In the following embodiments, components identical to those in the above-described embodiment will be denoted by the same reference symbols, and a redundant description thereof will not be made or will be made in brief, and the differences in them from the above-described embodiment will be mainly described.

FIGS. 8 to 17 are cross-sectional views illustrating cross sections of semiconductor devices according to some embodiments. Specifically, FIGS. 8 to 17 are partial enlarged views illustrating regions P2 to P11 according to some embodiments which correspond to region P1 of FIG. 5.

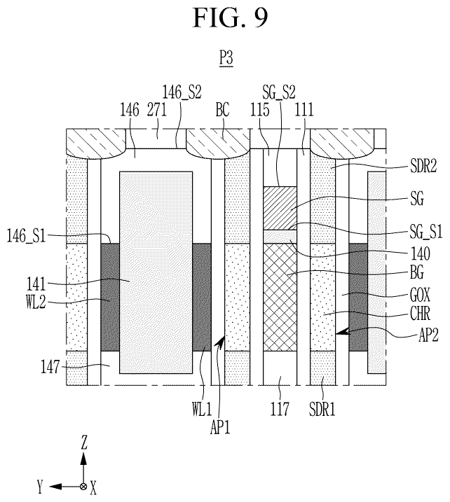

A semiconductor device according to an embodiment shown in FIGS. 8 and 9 is different from the semiconductor device according to the above-described embodiment in the arrangement of the shield gate SG.

According to the embodiment shown in FIG. 8, unlike in the semiconductor device according to the above embodiment, the shield gate SG may be positioned on the word lines WL1 and WL2 and may not be positioned on the back gate electrode BG. In other words, unlike in the embodiment shown in FIG. 7, the first shield gate (see the reference symbol “SG1” in FIG. 7) which is positioned on the back gate electrode BG may be omitted.

Further, as the shield gate SG is omitted on the back gate electrode BG, unlike in the embodiment shown in FIG. 7, the first shield isolation pattern (see the reference symbol “113” in FIG. 7) which is positioned on the back gate electrode BG may be omitted.

In the present embodiment, on one side of the second dopant region SDR2 of each of the active patterns AP1 and AP2, the shield gate SG may be positioned, and on the other side, a back gate capping pattern 116 may be positioned.

Specifically, the back gate capping pattern 116 which is positioned on the back gate electrode BG may include a first surface 116_S1 and a second surface 116_S2 which face each other in the third direction Z.

In the present embodiment, the first surface 116_S1 of the back gate capping pattern 116 may be in contact with the back gate electrode BG, and the second surface 116_S2 may be in contact with the contact interlayer insulating layer 271.

The thickness of the back gate capping pattern 116 in the third direction Z may be larger than the thickness of the shield gate SG in the third direction Z. However, the present disclosure is not limited thereto, and the relationship of the thickness of the back gate capping pattern 116 in the third direction Z and the thickness of the shield gate SG in the third direction Z may be variously changed.

The shield gate SG which is positioned on the word lines WL1 and WL2 may include a first surface SG_S1 and a second surface SG_S2 which face each other in the third direction Z.

The first surface 116_S1 of the back gate capping pattern 116 may be positioned at a level different from that of the first surface SG_S1 of the shield gate SG, and the second surface 116_S2 of the back gate capping pattern 116 may be positioned at a level different from that of the second surface SG_S2 of the shield gate SG. For example, the first surface 116_S1 of the back gate capping pattern 116 may be positioned at a lower level than the first surface SG_S1 of the shield gate SG, and the second surface 116_S2 of the back gate capping pattern 116 may be positioned at a higher level than the second surface SG_S2 of the shield gate SG.

Further, the first surface 116_S1 of the back gate capping pattern 116 may be positioned substantially at the same level as that of the lower surface of a shield isolation pattern 140 which is in contact with the word lines WL1 and WL2. However, the present disclosure is not limited thereto, and the arrangement relationship of the back gate capping pattern 116 and the shield gate SG and/or the arrangement relationship of the back gate capping pattern 116 and the shield isolation pattern 140 may be variously changed. For example, when the upper surface of the back gate electrode BG is formed so as to be positioned at a higher level than the upper surfaces of the word lines WL1 and WL2, the first surface 116_S1 of the back gate capping pattern 116 may be positioned at a level different from that of the lower surface of the shield isolation pattern 140.

According to the embodiment shown in FIG. 9, unlike in the semiconductor device according to the above embodiment, the shield gate SG may be positioned on the back gate electrode BG, and may not be positioned on the word lines WL1 and WL2. In other words, unlike in the embodiment shown in FIG. 7, the second shield gate (see the reference symbol “SG2” in FIG. 7) which is positioned on the word lines WL1 and WL2 may be omitted.

Further, as the shield gate SG is omitted on the word lines WL1 and WL2, unlike in the embodiment shown in FIG. 7, the second shield isolation pattern (see the reference symbol “143” in FIG. 7) which is positioned on the word lines WL1 and WL2 may be omitted.

In the present embodiment, on one side of the second dopant region SDR2 of each of the active patterns AP1 and AP2, the shield gate SG may be positioned, and on the other side, a word line capping pattern 146 may be positioned.

Specifically, the word line capping pattern 146 may include a first surface 146_S1 which is in contact with the word lines WL1 and WL2, and a second surface 146_S2 which is in contact with the contact interlayer insulating layer 271.

The shield gate SG which is positioned on the back gate electrode BG may include the first surface SG_S1 and the second surface SG_S2 which oppose each other in the third direction Z.

The first surface 146_S1 of the word line capping pattern 146 may be positioned at a level different from that of the first surface SG_S1 of the shield gate SG, and the second surface 146_S2 of the word line capping pattern 146 may be positioned at a level different from that of the second surface SG_S2 of the shield gate SG. For example, the first surface 146_S1 of the word line capping pattern 146 may be positioned at a lower level than the first surface SG_S1 of the shield gate SG, and the second surface 146_S2 of the word line capping pattern 146 may be positioned at a higher level than the second surface SG_S2 of the shield gate SG.

Further, the first surface 146_S1 of the word line capping pattern 146 may be positioned substantially at the same level as that of the first surface of the shield isolation pattern 140 which is in contact with the back gate electrode BG. However, the present disclosure is not limited thereto, and the arrangement relationship of the word line capping pattern 146 and the shield gate SG and/or the arrangement relationship of the word line capping pattern 146 and the shield isolation pattern 140 may be variously changed. For example, when the upper surfaces of the word lines WL1 and WL2 are formed so as to be positioned at a higher level than the upper surface of the back gate electrode BG, the first surface 146_S1 of the word line capping pattern 146 may be positioned at a level different from that of the lower surface of the shield isolation pattern 140.

The embodiments shown in FIGS. 8 and 9 may be the results of forming the shield gate SG which is positioned on the word lines WL1 and WL2 and the shield gate SG which is positioned on the back gate electrode BG by separate processes. In other words, as any one of the process step of forming the shield gate SG which is positioned on the word lines WL1 and WL2 and the process step of forming the shield gate SG which is positioned on the back gate electrode BG is omitted, like in the embodiments shown in FIGS. 8 and 9, on only either the word lines WL1 and WL2 or the back gate electrode BG, the shield gate SG may be formed.

The semiconductor devices according to the embodiments shown in FIGS. 8 and 9 may have substantially the same effect as that of the semiconductor device according to the above embodiment. In other words, as the shield gate SG is formed on one side of each of the active patterns AP1 and AP2, coupling due to interference between the dopant regions of the active patterns AP1 and AP2 adjacent to each other with the word lines WL1 and WL2 interposed therebetween or between the dopant regions of the active patterns AP1 and AP2 adjacent to each other with the back gate electrode BG interposed therebetween can be improved.

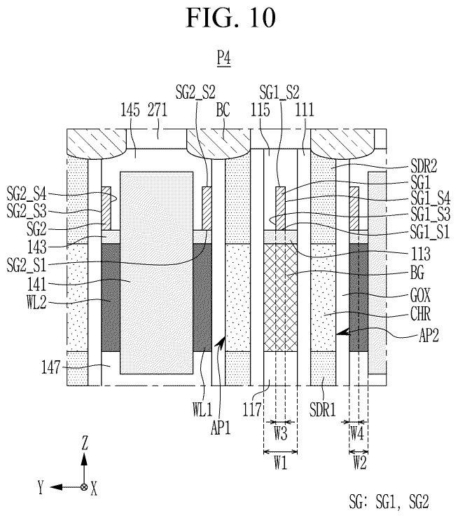

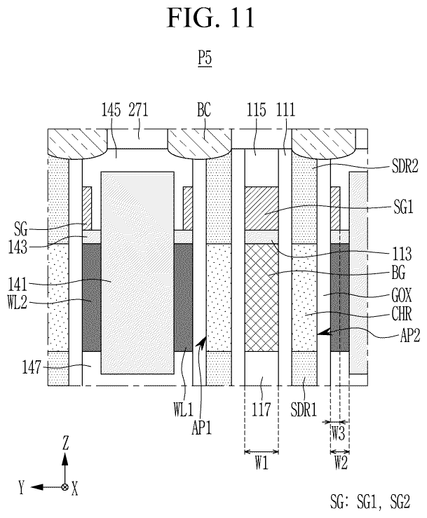

The semiconductor devices according to the embodiments shown in FIGS. 10 and 11 are different from the semiconductor device according to the above embodiment in that the width of the shield gate SG is changed.

The embodiment shown in FIG. 10 is different from the semiconductor device according to the above embodiment in that the width of the first shield gate SG1 which is positioned on the back gate electrode BG is smaller than the width of the back gate electrode BG, and the width of the second shield gate SG2 which is positioned on the word lines WL1 and WL2 is smaller than the width of each of the word lines WL1 and WL2.

Specifically, the back gate electrode BG may have a first width W1, and each of the word lines WL1 and WL2 may have a second width W2, and the first shield gate SG1 may have a third width W3, and the second shield gate SG2 may have a fourth width W4. Here, the first width W1, the second width W2, the third width W3, and the fourth width W4 may refer to widths in the second direction Y.

In the present embodiment, the first width W1 may be larger than the third width W3, and the second width W2 may be larger than the fourth width W4. In other words, the width of the back gate electrode BG may be larger than the width of the first shield gate SG1, and the width of each of the word lines WL1 and WL2 may be larger than the width of the second shield gate SG2.

Further, in the present embodiment, the third width W3 may be substantially the same as the fourth width W4. However, the relationship of the third width W3 and the fourth width W4 is not limited thereto, and may be variously changed. For example, the third width W3 may be larger or smaller than the fourth width W4.

In the present embodiment, the first shield gate SG1 may be entirely surrounded by the first shield capping pattern 115. In other words, the second surface SG1_S2 of the first shield gate SG1, and a first side surface SG1_S3 and second side surface SG1_S4 of the first shield gate SG1 may be in contact with the first shield capping pattern 115.

In the present embodiment, the first side surface SG2_S3 and second surface SG2_S2 of the second shield gate SG2 which is positioned on the first word line WL1 among the plurality of second shield gates SG2 may be in contact with the second shield capping pattern 145, and the second side surface SG2_S4 may be in contact with the gate insulating pattern GOX.

Further, the first side surface SG2_S3 of the second shield gate SG2 which is positioned on the second word line WL2 among the plurality of second shield gates SG2 may be in contact with the gate insulating pattern GOX, and the second side surface SG2_S4 and the second surface SG2_S2 may be in contact with the second shield capping pattern 145.

In the present embodiment, the first shield gate SG1 and the back gate electrode BG may have substantially the same central axis. In other words, the center of the first shield gate SG1 and the center of the back gate electrode BG may be positioned so as to be aligned on substantially the same central axis.

The second shield gate SG2 may have a central axis different from that of each of the word lines WL1 and WL2. In other words, the central axes of the second shield gates SG2 may be shifted from the central axes of the word lines WL1 and WL2 to one side or the other side in the second direction Y, respectively. For example, as the central axes of the second shield gates SG2 are shifted from the central axes of the word lines WL1 and WL2 to one side or the other side in the second direction Y, respectively, the second shield gates SG2 may be positioned closer to the gate insulating pattern GOX of the gate isolation pattern 141 and the gate insulating pattern GOX. However, the positioned on the second shield gate SG2 is not limited thereto, and may be variously changed. For example, unlike in FIG. 10, the central axes of the second shield gates SG2 may be positioned so as to coincide with the central axes of the word lines WL1 and WL2, respectively.

The semiconductor device according to the embodiment shown in FIG. 11 is different from the semiconductor device according to the embodiment shown in FIG. 10 in that the widths of the first shield gate SG1 and the second shield gate SG2 are different.

Specifically, referring to FIG. 11, the back gate electrode BG and the first shield gate SG1 may have a first width W1. In other words, the back gate electrode BG and the first shield gate SG1 may have substantially same width.

Each of the word lines WL1 and WL2 may have a second width W2, and the second shield gate SG2 may have a third width W3. Here, the first width W1, the second width W2, and the third width W3 may refer to the widths in the second direction Y.

In the present embodiment, the first width W1 may be larger than the second width W2 and the third width W3, and the second width W2 may be larger than the third width W3. In other words, the width of the back gate electrode BG may be larger than the width of each of the word lines WL1 and WL2, and be substantially the same as the width of the first shield gate SG1.

The width of the first shield gate SG1 may be larger than the width of each of the word lines WL1 and WL2 and the width of the second shield gate SG2. The width of the second shield gate SG2 may be smaller than each of the width of the word lines WL1 and WL2. However, the relationship of the first width W1, the second width W2, and the third width W3 may not limited thereto, and may be variously changed. For example, unlike in FIG. 11, the width of the first shield gate SG1 may be smaller than the width of the back gate electrode BG, and the width of the second shield gate SG2 may be substantially the same as the width of each of the word lines WL1 and WL2. In this case, the width of the first shield gate SG1 may be smaller or larger than the width of the second shield gate SG2.

The embodiments shown in FIGS. 10 and 11 may be the results of forming the width of the shield gate SG smaller than the widths of the word lines WL1 and WL2 and/or the width of the back gate electrode BG in the process step of forming the shield gates SG which are positioned on the word lines WL1 and WL2 and the shapes of which is positioned on the back gate electrode BG.

The semiconductor devices according to the embodiments shown in FIGS. 10 and 11 may have substantially the same effect as that of the semiconductor device according to the above embodiment.

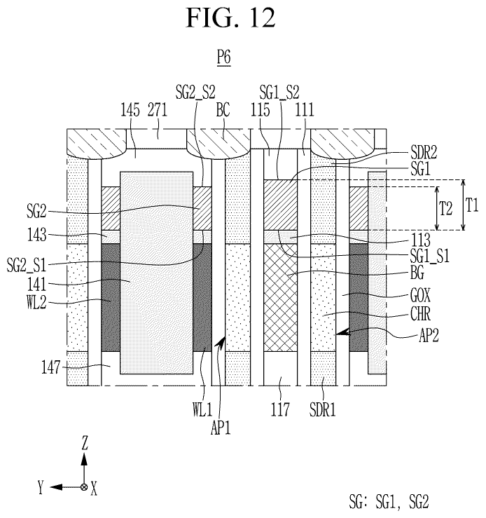

Semiconductor devices according to embodiments shown in FIGS. 12 to 14 may be different the semiconductor device according to the above embodiment in that the thickness of the shield gate SG and/or the shield isolation patterns 113 and 143 in the third direction Z are changed.

The semiconductor device according to the embodiment shown in FIG. 12 is different from the semiconductor device according to the above embodiment in that the thickness of the first shield gate SG1 in the third direction Z and the thickness of the second shield gate SG2 in the third direction Z are different.

In the present embodiment, the thicknesses of the first shield isolation pattern 113 and the second shield isolation pattern 143 in the third direction Z may be substantially the same.

In the present embodiment, the first shield gate SG1 may have a first thickness T1, and the second shield gate SG2 may have a second thickness T2. Here, the first thickness T1 may refer to the thickness of the first shield gate SG1 between the first surface SG1_S1 and the second surface SG1_S2 in the third direction Z, and the second thickness T2 may refer to the thickness of the second shield gate SG2 between the first surface SG2_S1 and the second surface SG2_S2 in the third direction Z.

In the present embodiment, the first thickness T1 may be larger than the second thickness T2. In other words, the thickness of the first shield gate SG1 may be larger than the thickness of the second shield gate SG2. However, the present disclosure is not limited thereto, and the relationship of the first thickness T1 and the second thickness T2 may be variously changed. For example, the first thickness T1 may be smaller than the second thickness T2.

In the present embodiment, the first surface SG1_S1 of the first shield gate SG1 may be positioned substantially at the same level as that of the first surface SG2_S1 of the second shield gate SG2, and the second surface SG1_S2 of the first shield gate SG1 may be positioned at a higher level than the second surface SG2_S2 of the second shield gate SG2. However, the present disclosure is not limited thereto, and as the thickness of the first shield gate SG1 and the thickness of the second shield gate SG2 are changed and/or the thicknesses of the first shield isolation pattern 113 and the second shield isolation pattern 143 are changed, the relationship of the first shield gate SG1 and the second shield gate SG2 may be variously changed.

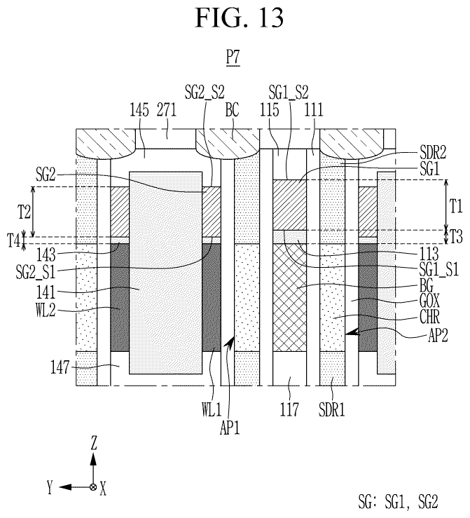

The semiconductor device accuracy of the embodiment shown in FIG. 13 is different from the semiconductor device according to FIG. 12 in that the thicknesses of the first shield isolation pattern 113 and the second shield isolation pattern 143 in the third direction Z are different.

In the present embodiment, the first shield gate SG1 may have a first thickness T1, the second shield gate SG2 may have a second thickness T2, the first shield isolation pattern 113 may have a third thickness T3, and the second shield isolation pattern 143 may have a fourth thickness T4.

Here, the first thickness T1, the second thickness T2, the third thickness T3, and the fourth thickness T4 may refer to the thicknesses in the third direction Z.

In the present embodiment, the first thickness T1 may be substantially the same as the second thickness T2, and the third thickness T3 may be larger than the fourth thickness T4. In other words, the thicknesses of the first shield gate SG1 and the second shield gate SG2 may be substantially the same, and the thickness of the first shield isolation pattern 113 may be larger than the thickness of the second shield isolation pattern 143.

Accordingly, the first surface of the first shield isolation pattern 113 may be positioned substantially at the same level as that of the first surface of the second shield isolation pattern 143, and the second surface of the first shield isolation pattern 113 may be positioned at higher level than the second surface of the second shield isolation pattern 143. Here, the first surface of each of the first and second shield isolation patterns 113 and 143 may correspond to the lower surface, and the second surface may correspond to the upper surface.

Further, the first surface SG1_S1 of the first shield gate SG1 may be positioned at a higher level than that of the first surface SG2_S1 of the second shield gate SG2, and the second surface SG1_S2 of the first shield gate SG1 may be positioned at a higher level than that of the second surface SG2_S2 of the second shield gate SG2.

Unlike in FIG. 13, in some embodiments, the first thickness T1 and the second thickness T2 may be substantially the same, and the third thickness T3 may be smaller than the fourth thickness T4. The lower surface of the first shield isolation pattern 113 may be positioned substantially at the same level as that of the lower surface of the second shield isolation pattern 143, and the upper surface of the first shield isolation pattern 113 may be positioned at a level lower than that of the upper surface of the second shield isolation pattern 143.

Accordingly, the first surface SG1_S1 of the first shield gate SG1 may be positioned at a level lower than that of the first surface SG2_S1 of the second shield gate SG2, and the second surface SG1_S2 of the first shield gate SG1 may be positioned at a level lower than that of the second surface SG2_S2 of the second shield gate SG2. However, the present disclosure is not limited thereto, and as the thicknesses of the word lines WL1 and WL2 in the third direction Z and/or the thickness of the back gate electrode BG in the third direction Z is variously changed, the relationship of the first and second shield isolation patterns 113 and 143 and the first and second shield gates SG1 and SG2 may be variously changed.

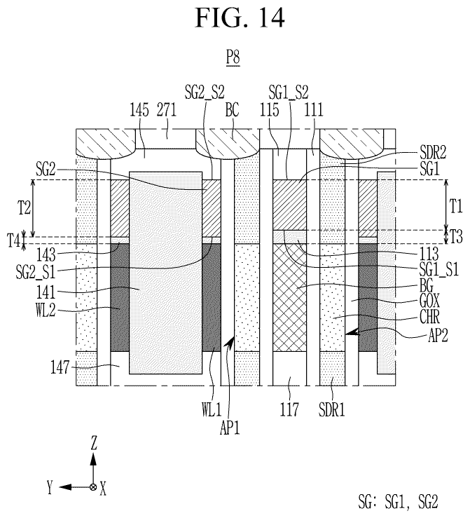

The semiconductor device according to the embodiment shown in FIG. 14 is different from the semiconductor device according to the embodiment shown in FIG. 13 in that the thicknesses of the first shield isolation pattern 113 and the second shield isolation pattern 143 in the third direction Z are different and the thicknesses of the first shield gate SG1 and the second shield gate SG2 are different.

Referring to FIG. 14, in the present embodiment, the first thickness T1 may be smaller than the second thickness T2, and the third thickness T3 may be larger than the fourth thickness T4. In other words, the thickness of the first shield gate SG1 may be smaller than the thickness of the second shield gate SG2, and the thickness of the first shield isolation pattern 113 may be larger than the thickness of the second shield isolation pattern 143.

The lower surface of the first shield isolation pattern 113 may be positioned substantially at the same level as that of the lower surface of the second shield isolation pattern 143, and the upper surface of the first shield isolation pattern 113 may be positioned at a higher level than that of the upper surface of the second shield isolation pattern 143.

Further, the first surface SG1_S1 of the first shield gate SG1 may be positioned at a higher level than that of the first surface SG2_S1 of the second shield gate SG2, and the second surface SG1_S2 of the first shield gate SG1 may be positioned substantially at the same level as that of the second surface SG2_S2 of the second shield gate SG2. However, the present disclosure is not limited thereto. For example, the first surface SG1_S1 of the first shield gate SG1 may be positioned at a higher level than that of the first surface SG2_S1 of the second shield gate SG2, and the second surface SG1_S2 of the first shield gate SG1 may be positioned at a level different from that of the second surface SG2_S2 of the second shield gate SG2.

The embodiments shown in FIGS. 12 to 14 may be the results of forming the shield gates SG which are formed on the word lines WL1 and WL2 and the shield gate SG which is formed on the back gate electrode BG such that the thicknesses of the shield gates SG and/or the thicknesses of the shield isolation patterns 113 and 143 are different.

The semiconductor devices according to the embodiments shown in FIGS. 13 to 14 may have substantially the same effect as that of the semiconductor device according to the above embodiment.

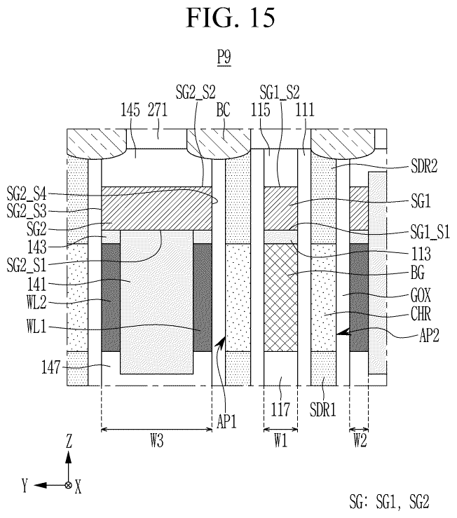

The semiconductor device according to the embodiment shown in FIG. 15 is different from the semiconductor device according to the above embodiment in that the arrangement of the second shield gates SG2 is changed.

The semiconductor device according to the embodiment shown in FIG. 15 is different from the semiconductor device according to the above embodiment in that the width of the second shield gates SG2 which are positioned on the word lines WL1 and WL2 is changed.

The above description of the first shield gate SG1 made with reference to FIG. 7 may also be substantially equally applied to the first shield gate SG1 according to the present embodiment, and thus a detailed description thereof will not be made.

Referring to FIG. 15, the back gate electrode BG and the first shield gate SG1 may have a first width W1, each of the word lines WL1 and WL2 may have a second width W2, and the second shield gate SG2 may have a third width W3. Here, the first width W1, the second width W2, and the third width W3 may refer to the widths in the second direction Y.

In the present embodiment, the first width W1 may be larger than the second width W2, and smaller than the third width W3. In other words, the widths of the back gate electrode BG and the first shield gate SG1 may be substantially the same, and each of the widths of the back gate electrode BG and the first shield gate SG1 may be larger than the widths of the word lines WL1 and WL2. Further, the width of the second shield gate SG2 may be larger than the width of the first shield gate SG1, the width of the back gate electrode BG, and the width of each of the word lines WL1 and WL2.

In the present embodiment, the second shield gate SG2 may be positioned so as to overlap the first and second word lines WL1 and WL2, which are positioned between the first active pattern AP1 and the second active pattern AP2, in the third direction Z. In other words, the second shield gate SG2 may be positioned so as to overlap the plurality of word lines WL1 and WL2 in the third direction Z.

The first surface SG2_S1 of the second shield gate SG2 may be in contact with the gate isolation pattern 141 and the second shield isolation pattern 143 which is positioned on both sides of the gate isolation pattern 141. The first side surface SG2_S3 and second side surface SG2_S4 of the second shield gate SG2 may be in contact with the gate insulating pattern GOX.

The upper surface of the gate isolation pattern 141 which is in contact with the first surface SG2_S1 of the second shield gate SG2 and the upper surface of the second shield isolation pattern 143 may be positioned substantially at the same level.

In the present embodiment, the first surface SG1_S1 of the first shield gate SG1 may be positioned substantially at the same level as that of the first surface SG2_S1 of the second shield gate SG2, and the second surface SG1_S2 of the first shield gate SG1 and the second surface SG2_S2 of the second shield gate SG2 may be substantially at the same level. However, the arrangement relationship of the first shield gate SG1 and the second shield gate SG2 is not limited thereto, and may be variously changed. For example, the first surface SG1_S1 of the first shield gate SG1 may be positioned substantially at the same level as that of the first surface SG2_S1 of the second shield gate SG2, and the second surface SG1_S2 of the first shield gate SG1 may be positioned at a level different from that of the second surface SG2_S2 of the second shield gate SG2. As another example, the first surface SG1_S1 of the first shield gate SG1 may be positioned at a level different from that of the first surface SG2_S1 of the second shield gate SG2, and the second surface SG1_S2 of the first shield gate SG1 may be positioned substantially at the same level as that of the second surface SG2_S2 of the second shield gate SG2. As a further example, the first surface SG1_S1 of the first shield gate SG1 may be positioned at a level different from that of the first surface SG2_S1 of the second shield gate SG2, and the second surface SG1_S2 of the first shield gate SG1 may be positioned at a level different from that of the second surface SG2_S2 of the second shield gate SG2.

The embodiment shown in FIG. 15 may be the result of forming the shield gates SG which are positioned on the word lines WL1 and WL2 and the shield gate SG which is positioned on the back gate electrode BG in separate process steps such as the width of the first shield gate SG1 and the width of the second shield gate SG2 are different.

The semiconductor device according to the embodiments shown in FIG. 15 may have substantially the same effect as that of the semiconductor device according to the above embodiment.

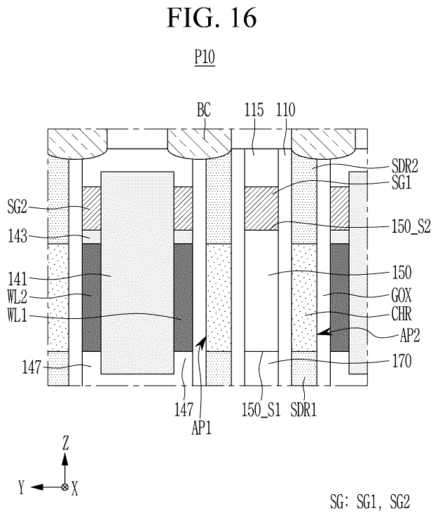

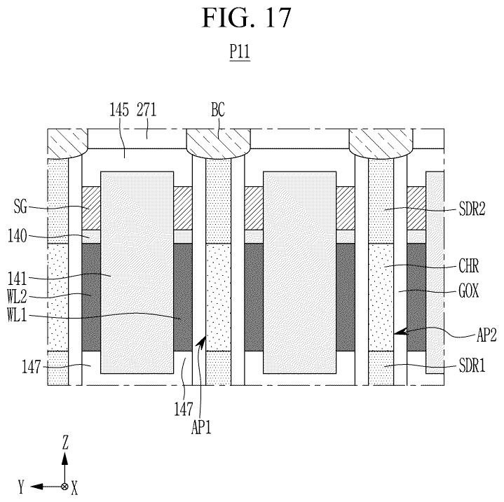

The semiconductor devices according to the embodiments shown in FIGS. 16 and 17 are different from the semiconductor device according to the above embodiment in that the back gate electrode BG is omitted.

According to the semiconductor device according to the embodiment shown in FIG. 16, unlike in the embodiment shown in FIG. 7, the back gate electrode BG, the first back gate insulating pattern 111, and the first shield isolation pattern 113 may be omitted, and an isolation insulating pattern 150 which is positioned between the first active pattern AP1 and the second active pattern AP2, an isolation capping pattern 170, and a first shield insulating pattern 110 which surrounds the side surfaces of the isolation insulating pattern 150 and the isolation capping pattern 170 may be further included.

Specifically, referring to FIG. 16, on one side of any one of the active patterns AP1 and AP2 in the second direction Y, the first word line WL1 may be positioned, and on the other side in the second direction Y, the isolation insulating pattern 150 may be positioned. Further, on one side of the other one of the active patterns AP1 and AP2 in the second direction Y, the isolation insulating pattern 150 may be positioned, and on the other side in the second direction Y, the second word line WL2 may be positioned.

Accordingly, the word lines WL1 and WL2 may be positioned only on one side or the other side of the active patterns AP1 and AP2.

The isolation insulating pattern 150 may include a first surface 150_S1 and a second surface 150_S2 which oppose each other in the third direction Z. Here, the first surface 150_S1 may correspond to the lower surface of the isolation insulating pattern 150, and the second surface 150_S2 may correspond to the upper surface.

The first surface 150_S1 of the isolation insulating pattern 150 may be positioned at a lower level than the lower surface of the second shield isolation pattern 143, and the second surface 150_S2 may be positioned substantially at the same level as that of the upper surface of the second shield isolation pattern 143. However, the present disclosure is not limited thereto, the second surface 150_S2 of the isolation insulating pattern 150 may be positioned at a level different from that of the upper surface of the second shield isolation pattern 143.

In the present embodiment, the first shield gate SG1 may be positioned on the second surface 150_S2 of the isolation insulating pattern 150, and the second shield gate SG2 may be positioned on the word lines WL1 and WL2.

The contents about the first shield gate SG1 and the second shield gate SG2 described above with reference to FIGS. 7 to 15 may be equally applied to the first shield gate SG1 and the second shield gate SG2 according to the present embodiment, and thus a detailed description thereof will not be made.

The isolation capping pattern 170 may be positioned on the first surface 150_S1 of the isolation insulating pattern 150. The first shield isolation pattern 110 may extend in the third direction Z along the side surfaces of each of the isolation capping pattern 170, the isolation insulating pattern 150, the first shield gate SG1, and the first shield capping pattern 115 sequentially stacked.

The first shield isolation pattern 110 may be positioned between the side surfaces of each of the isolation capping pattern 170, the isolation insulating pattern 150, the first shield gate SG1, and the first shield capping pattern 115 sequentially stacked and the active patterns AP1 and AP2.

Each of the first shield isolation pattern 110, the isolation insulating pattern 150, and the isolation capping pattern 170 may contain an insulating material. For example, the insulating material may include silicon oxide, silicon nitride, silicon oxynitride, etc., but is not limited thereto, and may be variously changed.

The semiconductor device according to the embodiment shown in FIG. 17 is different from the embodiment shown in FIG. 7 in that the back gate electrode BG which is positioned between the first active pattern AP1 and the second active pattern AP2, the first back gate insulating pattern 111, the first shield isolation pattern 113, and the first shield gate SG1 are omitted, and the first word line WL1 and the second word line WL2 are further included between the first active pattern AP1 and the second active pattern AP2.

Referring to FIG. 17, between each pair of active patterns AP1 and AP2, a first word line WL1 and a second word line WL2 may be positioned.

Specifically, on one side of the first active pattern AP1 in the second direction Y, the first word line WL1 may be positioned, and on the other side in the second direction Y, the second word line WL2 may be positioned. Further, on one side of the second active pattern AP2 in the second direction Y, the first word line WL1 may be positioned, and on the other side in the second direction Y, the second word line WL2 may be positioned.

Accordingly, on both sides of each of the first active pattern AP1 and the second active pattern AP2, the word lines WL1 and WL2 may be positioned.

In the present embodiment, the plurality of shield gates SG may be positioned on the plurality of word lines WL1 and WL2, respectively. The plurality of individual shield gates SG may have substantially the same thickness in the third direction Z and/or substantially the same width in the second direction Y. However, the present disclosure is not limited thereto, and the above description of the shield gates SG made with reference to FIGS. 10 to 15 may be equally applied to the arrangement relationship, width relationship, thickness relationship, and so on of the plurality of shield gates SG, and thus a detailed description thereof will not be made.

In FIG. 17, it is shown that two side surfaces of the side surfaces of each of the first active pattern AP1 and the second active pattern AP2 overlap the word lines WL1 and WL2; however, the arrangement relationship of the first and second active patterns AP1 and AP2 and the word lines WL1 and WL2 is not limited thereto, and may be variously changed.

Unlike in FIG. 17, in some embodiments, the word lines WL1 and WL2 may surround the side surfaces of each of the first active pattern AP1 and the second active pattern AP2. For example, the word lines WL1 and WL2 may be integrally formed, and have a gate-all-around (GAA) structure which surrounds four side surfaces of each of the first active pattern AP1 and the second active pattern AP2.

When the word lines WL1 and WL2 are integrally formed and have a structure which surrounds all of the side surfaces of each of the first active pattern AP1 and the second active pattern AP2 as described above, the shield isolation patterns 140, which are positioned on the first word line WL1 and the second word line WL2, respectively, may be integrally formed and have a structure which surrounds all of the side surfaces of each of the first active pattern AP1 and the second active pattern AP2.

Further, when the word lines WL1 and WL2 are integrally formed and have a structure which surrounds all of the side surfaces of each of the first active pattern AP1 and the second active pattern AP2 as described above, the shield gates SG which are positioned on the first word line WL1 and the second word line WL2, respectively, may be integrally formed and have a structure which surrounds all of the side surfaces of each of the first active pattern AP1 and the second active pattern AP2.

The semiconductor device according to the embodiments shown in FIG. 17 may have substantially the same effect as that of the semiconductor device according to the above embodiment.

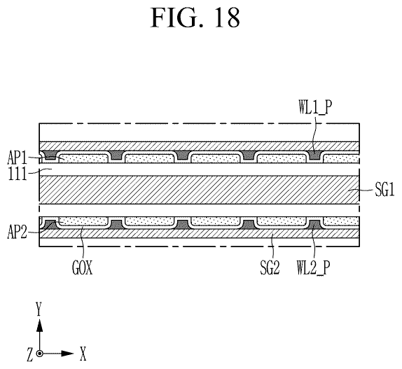

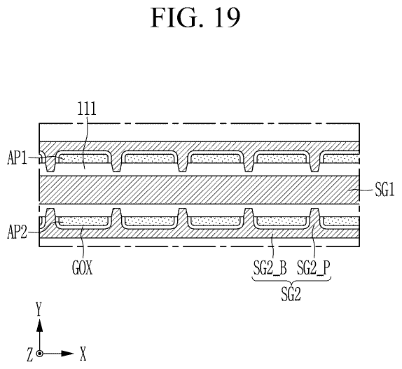

FIGS. 18 and 19 are plan views illustrating partial configurations of semiconductor devices according to some embodiments. In FIGS. 18 and 19, in order to illustrate the arrangement relationship of some components of the components included in the semiconductor devices according to some embodiments, the other components are not shown.

The semiconductor devices according to the embodiments shown in FIGS. 18 and 19 are different from the semiconductor device according to the above embodiment in that the planar shape of the shield gate SG is changed.

According to the embodiment shown in FIG. 18, the planar shape of the first shield gate SG1 may be substantially the same as the planar shape of the back gate electrode BG, and the planar shape of the second shield gate SG2 may be different from the planar shapes of the word lines WL1 and WL2.

Specifically, referring to FIG. 18 together with FIG. 3, the planar shape of the first shield gate SG1 may be substantially the same as the planar shape of the back gate electrode BG. However, the present disclosure is not limited thereto. For example, unlike in FIG. 18, the planar shape of the first shield gate SG1 may be different from the planar shape of the back gate electrode BG.

In the present embodiment, the planar shapes of the word lines WL1 and WL2 which overlap the second shield gate SG2 may be substantially the same as the planar shapes of the word lines WL1 and WL2 according to the embodiment shown in FIG. 3. The planar shape of the second shield gate SG2 may be different from the planar shapes of the word lines WL1 and WL2.

Specifically, the second shield gate SG2 may extend in the first direction X and have a line shape in a plan view. The planar shape of the second shield gate SG2 may be substantially the same as the planar shapes of the gate line portions WL1_B and WL2_B of the individual word lines WL1 and WL2.

The second shield gate SG2 may overlap a portion of each of the word lines WL1 and WL2 in the third direction Z. In other words, the second shield gate SG2 may overlap the gate line portions WL1_B and WL2_B of the individual word lines WL1 and WL2 in the third direction Z, and may not overlap the gate protrusion portions WL1_P and WL2_P of the individual word lines WL1 and WL2 in the third direction Z. Accordingly, by the second shield gate SG2, the gate protrusion portions WL1_P and WL2_P of the individual word lines WL1 and WL2 may be exposed.

In FIG. 18, it is shown that each of the first shield gate SG1 and the second shield gate SG2 has a line shape in a plan view; however, the planar shapes of the first shield gate SG1 and the second shield gate SG2 are not limited thereto, and may be variously changed.

Unlike in FIG. 18, in some embodiments, at least one of the first shield gate SG1 and the second shield gate SG2 may have an island shape in a plan view. For example, the first shield gates SG1 may have an island shape in a plan view and be partially positioned in a region of the entire region of the back gate electrode BG which overlaps the active patterns AP1 and AP2 in the second direction Y in a plan view. As another example, the second shield gate SG2 may have an island shape in a plan view, and be partially positioned in a region of the entire region of the word lines WL1 and WL2 which overlaps the active patterns AP1 and AP2 in the second direction Y in a plan view.

The embodiment shown in FIG. 19 is different from the embodiment shown in FIG. 2 in that the shape of the second shield gate SG2 is changed.

Referring to FIG. 19 together with FIG. 3, in the present embodiment, the planar shapes of the word lines WL1 and WL2 which overlap the second shield gate SG2 may be substantially the same as the planar shapes of the word lines WL1 and WL2 according to the embodiment shown in FIG. 3.

In the present embodiment, the shield line portion SG2_B of the second shield gate SG2 may have substantially the same shape as that of the gate line portions WL1_B and WL2_B of the individual word lines WL1 and WL2 which overlap it in the third direction Z.

In the present embodiment, in a plan view, the length of the shield protrusion portion SG2_P of the second shield gate SG2 in the second direction Y may be larger than the lengths of the gate protrusion portions WL1_P and WL2_P of the individual word lines WL1 and WL2 in the second direction Y. In other words, in a plan view, an end of the shield protrusion portion SG2_P of the second shield gate SG2 may be positioned so as to further protrude in the second direction Y than the gate protrusion portions WL1_P and WL2_P of the individual word lines WL1 and WL2.

Accordingly, in a plan view, the shield protrusion portion SG2_P of the second shield gate SG2 may be positioned closer to a side surface of the back gate electrode BG and a side surface of the first shield gate SG1 than the gate protrusion portions WL1_P and WL2_P of the individual word lines WL1 and WL2.

In FIG. 19, it is shown that the first shield gate SG1 and the second shield gate SG2 are positioned apart; however, the planar shapes of the first shield gate SG1 and the second shield gate SG2 are not limited thereto, and may be variously changed. For example, the first shield gate SG1 and the second shield gate SG2 may be integrally formed. For example, as the shield protrusion portion SG2_P of the second shield gate SG2 extends to a side surface of the first shield gate SG1 in the second direction Y, the first shield gate SG1 and the second shield gate SG2 may be integrally formed.

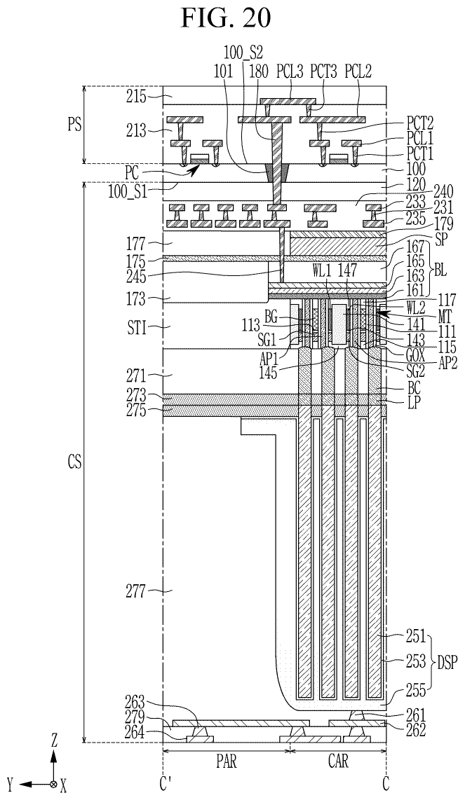

FIG. 20 is a cross-sectional view illustrating a cross section of a semiconductor device according to some embodiments.

The semiconductor device according to the embodiment shown in FIG. 20 is different from the semiconductor device according to the above embodiment in that the stack structure of the cell structure CS and the peripheral circuit structure PS and the connection method of the cell structure CS and the peripheral circuit structure PS are changed.

In the present embodiment, the peripheral circuit structure PS may be positioned on the cell structure CS. In other words, the cell structure CS and the peripheral circuit structure PS may be sequentially stacked, and positioned so as to overlap in the third direction Z.

Specifically, the substrate 100 may include a first surface 100_S1 and a second surface 100_S2 which face each other in the third direction Z. Here, the first surface 100_S1 may correspond to the lower surface of the substrate 100, and the second surface 100_S2 may correspond to the upper surface of the substrate 100.

The cell structure CS may be positioned on the first surface 100_S1 of the substrate 100, and the peripheral circuit structure PS may be positioned on the second surface 100_S2 of the substrate 100. Accordingly, the cell structure CS, the substrate 100, and the peripheral circuit structure PS may be sequentially stacked.

In the present embodiment, the peripheral circuit structure PS may include a first peripheral circuit insulating layer 213 and a second peripheral circuit insulating layer 215 sequentially stacked on the second surface 100_S2 of the substrate 100.

The peripheral circuit structure PS may include the peripheral circuit PC, the peripheral circuit contacts PCT1, PCT2, and PCT3, the peripheral circuit wiring lines PCL1, PCL2, and PCL3, and the first and second peripheral circuit insulating layers 213 and 215.

In the present embodiment, the peripheral circuit PC may be positioned on the second surface 100_S2 of the substrate 100, and the first peripheral circuit insulating layer 213 may cover the peripheral circuit PC.

The first peripheral circuit contact PCT1, the second peripheral circuit contact PCT2, the first peripheral circuit wiring line PCL1, the second peripheral circuit wiring line PCL2, and the third peripheral circuit contact PCT3 may be positioned inside the first peripheral circuit insulating layer 213. The third peripheral circuit wiring line PCL3 may be positioned inside the second peripheral circuit insulating layer 215.

The first peripheral circuit wiring line PCL1 may be connected to the peripheral circuit PC through the first peripheral circuit contact PCT1, and the first peripheral circuit wiring line PCL1 and the second peripheral circuit wiring line PCL2 may be connected through the second peripheral circuit contact PCT2. The third peripheral circuit wiring line PCL3 may be connected to the second peripheral circuit wiring line PCL2 through the second peripheral circuit contact PCT2.

The third peripheral circuit wiring line PCL3 may be, for example, an input/output pad for connecting the semiconductor device to the outside. However, this is an example, and the function of the third peripheral circuit wiring line PCL3 may be variously changed.

The materials which are contained in the first to third peripheral circuit wiring lines PCL1, PCL2, and PCL3 and the first to third peripheral circuit contacts PCT1, PCT2, and PCT3 for connecting them according to the present embodiment are substantially the same as those of the peripheral circuit wiring lines PCL1 and PCL2 and/or the peripheral circuit contacts PCT1 and PCT2 according to the above embodiment, and thus a description thereof will not be made.

In FIG. 20, it is shown that the peripheral circuit structure PS includes the first to third peripheral circuit wiring lines PCL1, PCL2, and PCL3 and the first to third peripheral circuit contacts PCT1, PCT2, and PCT3 for connecting them; however, the numbers of peripheral circuit wiring lines and peripheral circuit contacts which are included in the peripheral circuit structure PS and/or the connection relationship of them may be variously changed.

In the present embodiment, the cell structure CS may include a cell wiring insulating layer 240 that covers the first cell insulating layer 177 and the shield capping pattern 179, first and second cell connection wiring lines 233 and 235 that are positioned inside the cell wiring insulating layer 240, and a cell connection wiring contact 231 that connect the first and second cell connection wiring lines 233 and 235.

According to the semiconductor device according to the present embodiment, one surface of the cell structure CS may be positioned so as to face the first surface 100_S1 of the substrate 100, and the other surface of the peripheral circuit structure PS may be positioned so as to face the second surface 100_S2 of the substrate 100.

Here, one surface of the cell structure CS may refer to the back surface of the cell structure CS, and the other surface of the peripheral circuit structure PS may refer to the back surface of the peripheral circuit structure PS. For example, the cell wiring insulating layer 240 may constitute one surface of the cell structure CS, and the first peripheral circuit insulating layer 213 may constitute the other surface of the peripheral circuit structure PS.

The first cell connection wiring line 233, the second cell connection wiring line 235, and the cell connection wiring contact 231 may be positioned inside the cell wiring insulating layer 240. The first cell connection wiring line 233 may be connected to the second cell connection wiring line 235 through the cell connection wiring contact 231.

In FIG. 20, it is shown that the second cell connection wiring line 235 is connected to the bit line BL through the bit line contact 245; however, the present disclosure is not limited thereto, and the second cell connection wiring line 235 may be connected to other components which are positioned in the cell structure CS.

The cell wiring insulating layer 240 may contain an insulating material. For example, the cell wiring insulating layer 240 may contain silicon oxide. The first cell connection wiring line 233, the second cell connection wiring line 235, and the cell connection wiring contact 231 may contain the same material as that of the cell connection wiring contact 231 and the cell connection wiring line 232 according to the above embodiment.

In FIG. 20, it is shown that the cell structure CS includes the first and second cell connection wiring lines 233 and 235 and the cell connection wiring contact 231 which connect them; however, the numbers of cell wiring lines and cell contacts which are included in the cell structure CS and/or the connection relationship thereof may be variously changed.

Further, in FIG. 20, it is shown that the cell wiring insulating layer 240 consists of a single layer; however, the present disclosure is not limited thereto, and the cell wiring insulating layer 240 may consist of multiple layers containing the same material and/or different materials.

The semiconductor device according to the present embodiment may further include a buffer layer 120 which is positioned between the substrate 100 and the cell structure CS, a through-hole via 180 which connects the cell structure CS and the peripheral circuit structure PS, and a spacer 101 which surrounds them.

The buffer layer 120 may be positioned between the first surface 100_S1 of the substrate 100 and one surface of the cell structure CS. The buffer layer 120 may contain an insulating material. For example, the insulating material may contain silicon oxide, etc., but is not limited thereto, and may be variously changed.

In the present embodiment, the cell structure CS and the peripheral circuit structure PS may be connected in a direct bonding manner by the single through-hole via 180.

The through-hole via 180 may extend in the third direction Z from the peripheral circuit structure PS to the cell structure CS. The through-hole via 180 may be a single through-hole via formed such that a portion is positioned in the cell structure CS and the other portion is positioned in the peripheral circuit structure PS. In other words, the single through-hole via 180 may pass through the first peripheral circuit insulating layer 213, the substrate 100, the buffer layer 120, and the cell wiring insulating layer 240.

The through-hole via 180 may connect the cell connection wiring lines 233 and 235 connected to the plurality of memory cells including the memory transistors MT and the cell capacitors DSP positioned in the cell structure CS, and the peripheral circuit wiring lines PCL1, PCL2, and PCL3 connected to the peripheral circuit PC positioned in the peripheral circuit structure PS. For example, the through-hole via 180 may connect the first cell connection wiring line 233 which is positioned in the cell structure CS and the second peripheral circuit wiring line PCL2 which is positioned in the peripheral circuit structure PS.

In FIG. 20, it is shown that one end of the through-hole via 180 is connected to the first cell connection wiring line 233 and the other end is connected to the second peripheral circuit wiring line PCL2; however, the connection relationship of the through-hole via 180, the cell structure CS, and the peripheral circuit structure PS is not limited thereto and may be variously changed.

The spacer 101 may be positioned inside the substrate 100. The spacer 101 may be positioned between the through-hole via 180 and the substrate 100 and surround the side surface of the through-hole via 180 passing through the substrate 100.

The through-hole via 180 may contain a conductive material. For example, the through-hole via 180 may contain the same conductive material as that of the first to third peripheral circuit contacts PCT1, PCT2, and PCT3 described above.

The spacer 101 may contain an insulating material. For example, the spacer 101 may contain silicon oxide. However, the present disclosure is not limited thereto, and the material which is contained in each of the through-hole via 180 and the spacer 101 may be variously changed.

Unlike in FIG. 20, in some embodiments, the cell structure CS, and the peripheral circuit structure PS which is positioned on the cell structure CS may be bonded and coupled by a hybrid copper bonding method, substantially like in the semiconductor device according to the embodiment shown in FIG. 4.

Further, unlike in FIG. 20, in some embodiments, the peripheral circuit structure PS and the cell structure CS may be sequentially stacked on the substrate 100, and the peripheral circuit structure PS and the cell structure CS may be connected in a direct bonding manner by the single through-hole via, substantially like in the present embodiment.

The embodiment shown in FIG. 20 may have substantially the same effect as that of the semiconductor device according to the above embodiment.

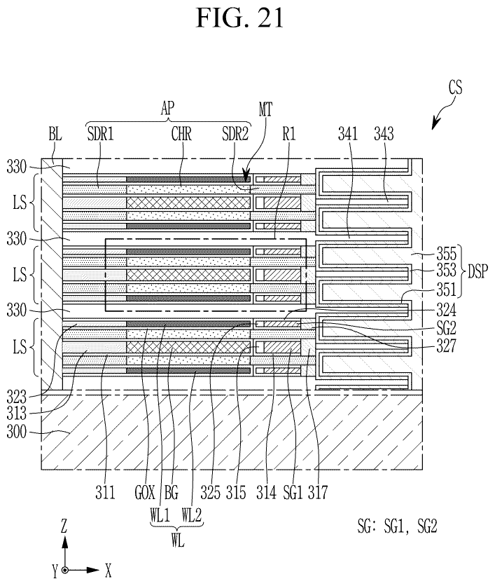

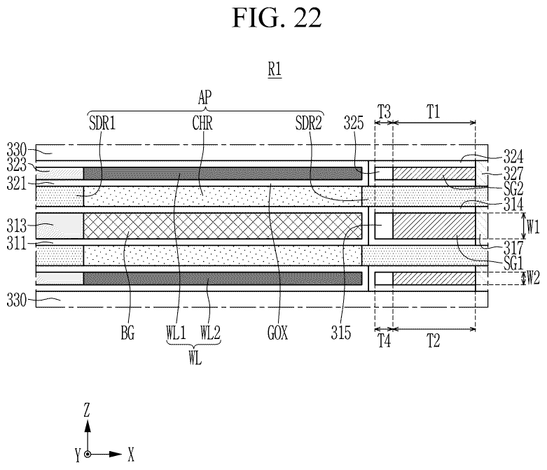

FIG. 21 is a cross-sectional view illustrating a cross section of a semiconductor device according to some embodiments. FIG. 22 is an enlarged view of region R1 of FIG. 21.

Specifically, FIG. 21 is a cross-sectional view illustrating a substrate 300 of the semiconductor device according to some embodiments and a cell structure CS which is positioned on the substrate 300. The semiconductor device according to the embodiment shown in FIG. 21 may be a vertically stacked DRAM (VS DRAM).

The semiconductor device according to the embodiment may include a plurality of memory cells arranged three-dimensionally. The plurality of memory cells may include one memory transistor MT and one cell capacitor DSP. Each of the plurality of memory cells may be connected to a bit line BL and a word line WL. In the present embodiment, two word lines WL may share one back gate electrode BG.

The semiconductor device according to the embodiment may include the substrate 300, and the cell structure CS which is positioned on the substrate 300.

The cell structure CS may include the substrate 300, a bit line BL which extends in the third direction Z perpendicular to the substrate 300, a plurality of active patterns AP which is connected to the bit line BL and extends in the first direction X parallel with the substrate 300, a pair of word lines WL which are positioned on both sides of the plurality of active patterns AP, a back gate electrode BG which is positioned between active patterns AP adjacent to each other, a cell capacitor DSP which is connected to the plurality of active patterns AP, and a plurality of shield gates SG which is positioned at a level between a word line WL and the cell capacitor DSP and/or at a level between the back gate electrode BG and the cell capacitor DSP.

In FIG. 21, it is shown that the semiconductor device according to the present embodiment includes three memory cells which are connected in common to one bit line BL and stacked in the third direction Z perpendicular to the substrate 300; however, the present disclosure is not limited thereto.

Further, in FIG. 21, it is shown that each stack structure LS includes one memory cell; however, the present disclosure is not limited thereto. For example, each stack structure LS may further include a memory cell mirror-symmetrical to the structure of the memory cell shown in FIG. 21. For example, the semiconductor device according to some embodiments may further include a stack structure mirror-symmetrical to the stack structure LS of FIG. 21 and positioned on the substrate 300. The stack structure LS and the stack structure mirror-symmetrical to the stack structure LS may form a pair.

Specifically, the substrate 300 may be, for example, a silicon substrate, a germanium substrate, or a silicon-germanium substrate. A plurality of stack structures LS may be sequentially stacked on the substrate 300. Each stack structure LS may constitute the memory cell array of the semiconductor device.

Although it is shown in FIG. 21, the semiconductor device according to the present embodiment may further include a peripheral circuit structure (not shown in the drawings) including a peripheral circuit for operating the memory cell array.

The peripheral circuit structure may include wiring lines which are electrically connected to the bit lines BL and the word lines WL, and the wiring lines may be connected to the peripheral circuit. The peripheral circuit structure may be positioned on or below the cell structure CS so as to overlap it in the third direction Z. For example, the cell structure CS and the peripheral circuit structure may be bonded and coupled by a hybrid copper bonding method substantially like in the semiconductor device according to the above embodiment. However, the bonding method of the cell structure CS and the peripheral circuit structure is not limited thereto. For example, the cell structure CS and the peripheral circuit structure may be connected in a direct bonding manner by the single through-hole via, substantially like in the semiconductor device according to the embodiment shown in FIG. 20.

Referring to FIGS. 21 and 22, on one side of the plurality of stack structures LS, a bit line BL may be positioned. The bit line BL may extend in the third direction Z perpendicular to the substrate 300. The bit line BL may have a line shape or a column shape extending in the third direction Z.

Each of the plurality of stack structures LS may include an active pattern AP, a pair of word lines WL which are positioned on both sides of the active pattern AP in the third direction Z, and a cell capacitor DSP which is connected to the active pattern AP. The pair of word lines WL may be positioned on both sides of the active pattern AP in the third direction Z.

The active pattern AP may extend in the first direction X vertically intersecting the extension direction of the bit line BL. In other words, the active pattern AP may extend in the first direction X parallel with the substrate 300.

The active pattern AP may include a first dopant region SDR1 which is connected to the bit line BL, a second dopant region SDR2 which is connected to the cell capacitor DSP, and a channel region CHR which is positioned between the first and second dopant regions SDR1 and SDR2. The second dopant region SDR2 of the active pattern AP may be connected to a first electrode 351 of the cell capacitor DSP to be described below.

The first and second dopant regions SDR1 and SDR2 of each of the active patterns AP1 and AP2 may correspond to the first source/drain electrode and second source/drain electrode of a memory transistor MT, and the channel region CHR may correspond to the channel of the memory transistor MT.

The above description of the active pattern AP made with reference to FIG. 7 may also be substantially equally applied to the active pattern AP according to the present embodiment, and thus a detailed description thereof will not be made.

The semiconductor device according to the present embodiment may further include an interlayer insulating layer 330 which is positioned between stack structures LS adjacent to each other.

The word lines WL, the active pattern AP, the back gate electrode BG, and the cell capacitor DSP which are included in each stack structure LS may be positioned on the interlayer insulating layer 330. The interlayer insulating layer 330 may be positioned between the substrate 300 and the stack structure LS positioned at the bottom.

The interlayer insulating layer 330 may contain, for example, at least one of silicon nitride, silicon oxynitride, carbon containing silicon oxide, carbon containing silicon nitride, or carbon containing silicon oxynitride.

The plurality of word lines WL may extend in the first direction X vertically intersecting the extension direction of the bit line BL. The plurality of word lines WL may extend in the first direction X parallel with the upper surface of the substrate 300.

The stack structure LS may include two word lines WL. The stack structure LS may include a first word line WL1 and a second word line WL2 spaced apart in the third direction Z. Between the first word line WL1 and the second word line WL2 spaced apart in the third direction Z, two active patterns AP may be positioned.

Each word line WL may be positioned so as to correspond to the channel region CHR of an active pattern AP. The first word line WL1 may be positioned on one side in the third direction Z of the channel region CHR of any one of the plurality of active patterns AP positioned adjacent to each other, and the second word line WL2 may be positioned on the other side in the third direction Z of the channel region CHR of the other one of the plurality of active patterns AP positioned adjacent to each other.

The material which is contained in the bit line BL and the word line WL according to the present embodiment is substantially the same as the material which is contained in the bit line BL and the word lines (see the reference symbols “WL1” and “WL2” in FIG. 4) included in the semiconductor device according to the above embodiment, and a detailed description thereof will not be made.

The semiconductor device according to the present embodiment may further include a gate capping pattern 323 which is positioned between the bit line BL and the word line WL, and a gate insulating pattern GOX which surrounds the side surfaces of the word line WL and the gate capping pattern 323.

The gate capping pattern 323 may contain an insulating material, and insulate the bit line BL and the word line WL from each other. For example, the gate capping pattern 323 may contain silicon oxide, silicon nitride, or a combination thereof.

The gate insulating pattern GOX may cover the side surfaces of the gate capping pattern 323 and the word line WL so as to conform to them.

The material which is contained in the gate insulating pattern GOX according to the present embodiment is substantially the same as the material which is contained in the gate insulating pattern GOX included in the semiconductor device according to the above embodiment, and thus, a detailed description thereof will not be made.

The stack structure LS may include one back gate electrode BG. The back gate electrode BG may be positioned between the first word line WL1 and the second word line WL2. The back gate electrode BG may be positioned between the active patterns AP adjacent to each other in the third direction Z. The back gate electrode BG may be positioned so as to correspond to the channel region CHR of an active pattern AP.

On one side of the active pattern AP in the third direction Z, the word line WL may be positioned, and on the other side in the third direction Z, the back gate electrode BG may be positioned. On both sides of the active pattern AP facing each other in the third direction Z, the word line WL and the back gate electrode BG may be positioned, respectively.

The material which is contained in the back gate electrode BG according to the present embodiment is substantially the same as the material which is contained in the back gate electrode BG included in the semiconductor device according to the above embodiment, and a detailed description thereof will not be made.

Further, in the present embodiment, regarding the arrangement relationship of the word line WL and the back gate electrode BG, the contents about the arrangement relationship of the word lines (see the reference symbols “WL1” and “WL2” in FIG. 7) and the back gate electrode BG according to the above embodiment may be substantially equally applied, and thus, a detailed description thereof will not be made.

The semiconductor device according to the present embodiment may further include a back gate capping pattern 313 which is positioned between the bit line BL and the back gate electrode BG, and a back gate insulating pattern 311 which surrounds the side surfaces of the back gate electrode BG and the back gate capping pattern 313.

The back gate capping pattern 313 may contain an insulating material, and insulate the bit line BL and the back gate electrode BG from each other. The back gate insulating pattern 311 may cover the side surfaces of the back gate capping pattern 313 and the back gate electrode BG so as to conform to them.

The back gate insulating pattern 311 and the back gate capping pattern 313 may contain silicon oxide, silicon nitride, or a combination thereof. However, the present disclosure is not limited thereto.

A plurality of shield gates SG may be positioned between the word line WL and the cell capacitor DSP and between the back gate electrode BG and the cell capacitor DSP.

In the present embodiment, a shield gate SG may overlap the second dopant region SDR2 of at least one of the plurality of active patterns AP in the third direction Z which is a vertical direction. For example, a shield gate SG may be positioned so as to overlap the second dopant region SDR2 of each of the plurality of active pattern AP in the third direction Z which is the vertical direction. In other words, the shield gate SG may be positioned so as to overlap a portion of the active pattern AP in the third direction Z which is the extension direction of the bit line BL.

The plurality of shield gates SG may include a plurality of first shield gates SG1 which is positioned on the back gate electrode BG, and a second shield gate SG2 which is positioned on the word line WL. In other words, a first shield gate SG1 may be positioned between the back gate electrode BG and the cell capacitor DSP, and a second shield gate SG2 may be positioned between the word line WL and the cell capacitor DSP.

In FIG. 22, it is shown that the plurality of shield gates SG is positioned between the back gate electrode BG and the cell capacitor DSP and between the word line WL and the cell capacitor DSP, respectively, but the arrangement of the plurality of shield gates SG is not limited thereto and may be variously changed. Although not shown in the drawing, for example, the plurality of shield gates SG may be arranged substantially in the same manner as that of the shield gates SG according to the embodiment shown in FIGS. 8 and 9.

Between a first shield gate SG1 and the back gate electrode BG, the back gate insulating pattern 311 may be positioned, and between the second shield gate SG2 and the word line WL, the gate insulating pattern GOX may be positioned.

Each first shield gate SG1 may be positioned so as to overlap the back gate electrode BG in the first direction X, and the second shield gate SG2 may be positioned so as to overlap the word line WL in the first direction X.

Each first shield gate SG1 may extend in the first direction X between the back gate electrode BG and the cell capacitor DSP, and the second shield gate SG2 may extend in the first direction X between the word line WL and the cell capacitor DSP.

The plurality of shield gates SG may be positioned between active patterns AP adjacent to each other in the third direction Z. The length of each shield gate SG in the first direction X may be smaller than the lengths of the active patterns AP1 and AP2 in the first direction X.

The length of a shield gate SG in the first direction X may be smaller than the length of the second dopant region SDR2 in the first direction X. Accordingly, the shield gate SG may overlap a portion of the second dopant region SDR2 in the third direction Z.

Besides that, regarding the material, arrangement relationship, width relationship, and thickness relationship of the plurality of shield gates SG, voltage which is applied to the plurality of shield gates SG, and so on, the above contents described with reference to FIGS. 7 to 15 may be substantially equally applied, and thus, a detailed description thereof will not be made.

The semiconductor device according to the present embodiment may further include a first shield liner pattern 314 and a first shield isolation pattern 315 which are positioned between the back gate electrode BG and the first shield gate SG1, a first shield capping pattern 317 which is positioned between the first shield gate SG1 and the cell capacitor DSP, a second shield liner pattern 324 and a second shield isolation pattern 325 which are positioned between the word line WL and the second shield gate SG2, and a second shield capping pattern 327 which is positioned between the second shield gate SG2 and the cell capacitor DSP.

The first shield liner pattern 314 may be positioned between the first shield gate SG1 and the second dopant region SDR2 of the active pattern AP, between the first shield isolation pattern 315 and the second dopant region SDR2 of the active pattern AP, and between the back gate insulating pattern 311 and the first shield isolation pattern 315. The first shield liner pattern 314 may extend along the surfaces of the first shield gate SG1 and the first shield isolation pattern 315 so as to conform to them.

The second shield liner pattern 324 may be positioned between the second shield gate SG2 and the second dopant region SDR2 of the active pattern AP, between the second shield isolation pattern 325 and the second dopant region SDR2 of the active pattern AP, and between the gate insulating pattern GOX and the second shield isolation pattern 325. The second shield liner pattern 324 may extend along the surfaces of the second shield gate SG2 and the second shield isolation pattern 325 so as to conform to them.

The first shield isolation pattern 315 may be positioned between the first shield gate SG1 and the first shield liner pattern 314 in contact with the back gate insulating pattern 311, and the second shield isolation pattern 325 may be positioned between the second shield gate SG2 and the second shield liner pattern 324 in contact with the gate insulating pattern GOX.

The first shield capping pattern 317 may be positioned between the first shield liner pattern 314 and the cell capacitor DSP and between the first shield gate SG1 and the cell capacitor DSP. The second shield capping pattern 327 may be positioned between the second shield liner pattern 324 and the cell capacitor DSP and between the second shield gate SG2 and the cell capacitor DSP.

The first shield liner pattern 314, the first shield isolation pattern 315, the first shield capping pattern 317, the second shield liner pattern 324, the second shield isolation pattern 325, and the second shield capping pattern 327 may contain an insulating material. For example, the insulating material may contain silicon oxide, silicon nitride, or a combination thereof. However, the insulating material is not limited thereto, and may be variously changed.

The cell capacitor DSP may include the first electrode 351, a second electrode 355, and a dielectric layer 353 which is interposed between the first electrode 351 and the second electrode 355.

The contents about the first electrode (see the reference symbol “251” in FIG. 4), the second electrode (see the reference symbol “252” in FIG. 4), and the dielectric layer (see the reference symbol “253” in FIG. 4) included in the cell capacitor DSP according to the above embodiment may also be substantially equally applied to the first electrode 351, the second electrode 355, and the dielectric layer 353 included in the cell capacitor DSP according to the present embodiment, and thus, a detailed description thereof will not be made.

The semiconductor device according to the present embodiment may further include first and second capacitor isolation patterns 341 and 343 which are positioned between the first electrodes 351 of the cell capacitors DSP.

The first and second capacitor isolation patterns 341 and 343 may be positioned between the first electrodes 351 of the cell capacitors DSP, and alternately stacked in the third direction Z.

The first capacitor isolation pattern 341 may extend in the first direction X from the interlayer insulating layer 330, and the second capacitor isolation pattern 343 may extend in the first direction X from the first shield capping pattern 317. The first electrode 351 of each cell capacitor DSP may be isolated and insulated by the first and second capacitor isolation patterns 341 and 343.

The first and second capacitor isolation patterns 341 and 343 may contain an insulating material such as silicon oxide. However, the present disclosure is not limited thereto.

As shown in FIG. 22, the first shield gate SG1 may have a first thickness T1, the second shield gate SG2 may have a second thickness T2, the first shield isolation pattern 315 may have a third thickness T3, and the second shield isolation pattern 325 may have a fourth thickness T4.

Here, the first thickness T1, the second thickness T2, the third thickness T3, and the fourth thickness T4 may refer to the thicknesses in the first direction X. In other words, the first thickness T1, the second thickness T2, the third thickness T3, and the fourth thickness T4 may refer to the thicknesses of the first shield gate SG1, the second shield gate SG2, the first shield isolation pattern 315, and the second shield isolation pattern 325 in their extension directions, respectively.

In the present embodiment, the first thickness T1 may be substantially the same as the second thickness T2, and the third thickness T3 may be substantially the same as the fourth thickness T4. Further, the first thickness T1 may be larger than the third thickness T3, and the second thickness T2 may be larger than the fourth thickness T4. However, the relationship of the first thickness T1, the second thickness T2, the third thickness T3, and the fourth thickness T4 may be variously changed.

For example, unlike in FIG. 22, in some embodiments, regarding the relationship of the first thickness T1, the second thickness T2, the third thickness T3, and the fourth thickness T4, the content about the relationship of the first thickness T1, the second thickness T2, the third thickness T3, and the fourth thickness T4 according to the embodiment shown in FIGS. 12 to 14 may be substantially equally applied. Accordingly, the arrangement relationship of the first shield gate SG1, the second shield gate SG2, the first shield isolation pattern 315, and the second shield isolation pattern 325, and so on may be variously changed.

In the present embodiment, the first shield gate SG1 may have a first width W1, and the second shield gate SG2 may have a second width W2. Here, the first width W1 and the second width W2 may refer to the widths in the third direction Z.

In the present embodiment, the first width W1 may be larger than the second width W2. Further, the first width W1 may be substantially the same as the width of the back gate electrode BG in the third direction Z, and the second width W2 may be substantially the same as the width of the word line WL in the third direction Z. However, the relationship of the first width W1 and the second width W2, the relationship of the first width W1 and the width of the back gate electrode BG, and the relationship of the second width W2 and the width of the word line WL are not limited thereto, and may be variously changed. For example, the first width W1 may be substantially the same as the second width W2.

Although not shown in the drawing, as another example, regarding the relationship of the first width W1 and the second width W2, the content about the relationship of the first width W1 and the second width W2 according to the embodiment shown in FIGS. 10 and 11 may be substantially equally applied.

Accordingly, the arrangement relationship of a shield gate SG, a back gate electrode BG, and a word line WL, the shape of a shield gate SG, the arrangement of the shield gates SG, and so on may be variously changed.

As a shield gate SG is formed between the dopant regions of active patterns AP which are connected to cell capacitors DSP, the semiconductor device according to the embodiment shown in FIG. 22 may have substantially the same effect as that of the semiconductor device according to the above embodiment.

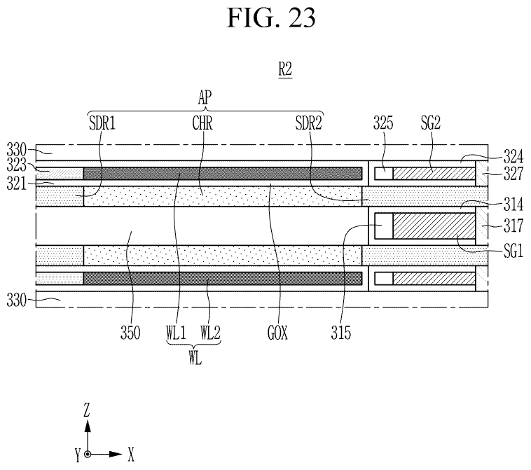

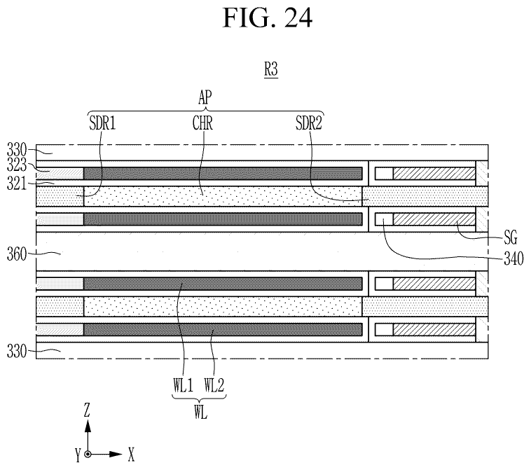

FIGS. 23 and 24 are cross-sectional views illustrating cross sections of semiconductor devices according to some embodiments. Specifically, FIGS. 23 and 24 are partial enlarged views illustrating region R2 and region R3 corresponding to region R1 of FIG. 21 according to some embodiments.

According to the semiconductor device according to the embodiment shown in FIG. 23, unlike in the embodiment shown in FIG. 22, the back gate electrode BG, the back gate insulating pattern 311, and the back gate capping pattern 313 may be omitted, and an isolation insulating pattern 350 which is positioned between active patterns AP adjacent to each other may be further included.

Specifically, referring to FIG. 23, on one side of any one of the plurality of active patterns AP in the third direction Z, a first word line WL1 may be positioned, and on the other side in the third direction Z, the isolation insulating pattern 350 may be positioned. Further, on one side of another one of the plurality of active patterns AP in the third direction Z, the isolation insulating pattern 150 may be positioned, and on the other side in the third direction Z, a second word line WL2 may be positioned. In other words, according to the present embodiment, a word line WL may be positioned only on either one side or the other side of an active pattern AP.

In the present embodiment, the first shield gate SG1 may be positioned so as to overlap the isolation insulating pattern 350 in the first direction X. The second shield gate SG2 may be positioned so as to overlap the word line WL in the first direction X. Although not shown in FIG. 23, the first shield gate SG1 may be positioned between the isolation insulating pattern 350 and a cell capacitor (see the reference symbol “DSP” in FIG. 21), and the second shield gate SG2 may be positioned between the word line WL and the cell capacitor DSP.

The isolation insulating pattern 350 may contain an insulating material. For example, the insulating material may include silicon oxide, silicon nitride, silicon oxynitride, etc., but is not limited thereto, and may be variously changed.

Besides that, regarding the shield gate SG according to the present embodiment, the contents about the shield gate SG according to the embodiment shown in FIG. 16 may be substantially equally applied, and thus, a detailed description thereof will not be made.

The semiconductor device according to the embodiment shown in FIG. 24 is different from the embodiment shown in FIG. 22 in that the back gate electrode BG, the back gate insulating pattern 311, the back gate capping pattern 313, the first shield liner pattern 314, the first shield isolation pattern 315, the first shield gate SG1, and the first shield capping pattern 317 which are positioned between active patterns AP adjacent to each other are omitted and a first word line WL1 and a second word line WL2 are further included between active patterns AP adjacent to each other.

According to the present embodiment, one stack structure (see the reference symbol “LS” in FIG. 22) may include four word lines WL.

Specifically, on one side in the third direction Z of any one of the plurality of active patterns AP included in one stack structure LS, a first word line WL1 may be positioned, and on the other side in the third direction Z, a second word line WL2 may be positioned. Further, on one side in the third direction Z of another one of the plurality of active patterns AP, a first word line WL1 may be positioned, and on the other side in the third direction Z, a second word line WL2 may be positioned.

Accordingly, on both sides in the third direction Z of each of the plurality of active patterns AP, word lines WL may be positioned. In other words, among the side surfaces of the plurality of active patterns AP, two side surfaces facing each other in the third direction Z, word lines WL may be positioned.

The semiconductor device according to the embodiment may further include a word line isolation pattern 360 which is positioned between a plurality of word lines WL and insulates and isolates them.

The word line isolation pattern 360 may be positioned between word lines WL adjacent in the third direction Z and isolate and insulate them. For example, the word line isolation pattern 360 may be positioned between the first word line WL1 which is positioned on one side in the third direction Z of any one of the plurality of active patterns AP and the second word line WL2 which is positioned on the other side in the third direction Z of another one of the plurality of active patterns AP.

The word line isolation pattern 360 may contain, for example, at least one of silicon nitride, silicon oxynitride, carbon containing silicon oxide, carbon containing silicon nitride, or carbon containing silicon oxynitride.

In the present embodiment, the plurality of shield gates SG may be positioned so as to the plurality of word lines WL in the first direction X. Although not shown in FIG. 24, the plurality of shield gates SG may be positioned between the word line WL and the cell capacitor (see the reference symbol “DSP” in FIG. 21).

In FIG. 24, it is shown that two side surfaces of the side surfaces of each of the plurality of active patterns AP overlap the word line WL; however, the arrangement relationship of each active pattern AP and the word line WL is not limited thereto, and may be variously changed.

Unlike in FIG. 24, in some embodiments, the word line WL may surround all of the side surfaces of each of the plurality of active patterns AP. For example, the word lines WL1 and WL2 may be integrally formed, and have a gate-all-around (GAA) structure which surrounds four side surfaces of each of the plurality of active patterns AP.

When the word lines WL1 and WL2 are integrally formed and have a structure which surrounds all of the side surfaces of each active pattern AP as described above, the shield isolation patterns 140, which are positioned on the first word line WL1 and the second word line WL2, may be integrally formed, and have a structure which surrounds all of the side surfaces of each active pattern AP.

Further, when the word lines WL1 and WL2 are integrally formed and have a structure which surrounds all of the side surfaces of each active pattern AP as described above, the shield gates SG which are positioned on the first word line WL1 and the second word line WL2, respectively, may be integrally formed and have a structure which surrounds all of the side surfaces of each active pattern AP.

The semiconductor device according to the embodiment shown in FIG. 23 may have substantially the same effect as that of the semiconductor device according to the embodiment shown in FIG. 16, and the semiconductor device according to the embodiment shown in FIG. 24 may have substantially the same effect as that of the semiconductor device according to the embodiment shown in FIG. 17.

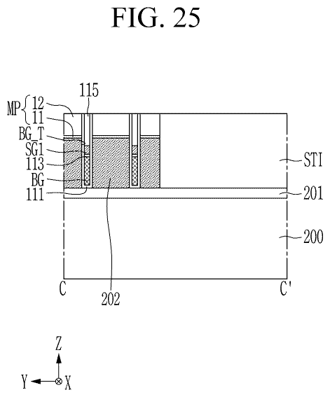

Hereinafter, a method of manufacturing the semiconductor device will be described with reference to FIGS. 25 to 33. Hereinafter, components identical to components described above will be denoted by the same reference symbols, and a redundant description thereof will not be made or will be made in brief, and the differences in them from the above-described components will be mainly described.

FIGS. 25 to 33 are cross-sectional views for explaining a method of manufacturing the semiconductor device according to the embodiment.

Specifically, FIGS. 25 to 33 are cross-sectional views taken along line C-C′ of FIG. 1 in individual manufacturing process steps for explaining the method of manufacturing the semiconductor device according to the embodiment.

First, referring to FIG. 25, a buried insulating layer 201 and an active layer 202 may be formed on a sub substrate 200. The sub substrate 200, the buried insulating layer 201, and the active layer 202 may be a silicon-on-insulator substrate (SOI substrate).

The buried insulating layer 201 may be, for example, buried oxide (BOX) formed by a separation by implanted oxygen (SIMOX) method or a bonding and layer transfer method. As another example, the buried insulating layer 201 may be an insulating layer formed by a chemical vapor deposition method.

The buried insulating layer 201 may contain, for example, silicon oxide, silicon nitride, silicon oxynitride, and/or a low-dielectric constant material.

The active layer 202 may be a monocrystalline semiconductor layer. The active layer 202 may be, for example, a monocrystalline silicon substrate, a germanium substrate, and/or a silicon-germanium substrate.

Subsequently, on the active layer 202, a mask pattern MP may be formed.

The mask pattern MP may include a first mask pattern 11 and a second mask pattern 12 sequentially stacked. The second mask pattern 12 may contain a material having etch selectivity to the first mask pattern 11. For example, the first mask pattern 11 may contain silicon oxide, and the second mask pattern 12 may contain silicon nitride; however, the present disclosure is not limited thereto.

Subsequently, inside the active layer 202, the element isolation layer STI may be formed. The element isolation layer STI may be formed inside the active layer 202 of the peripheral circuit region (see the reference symbol “PAR” in FIG. 5).

The element isolation layer STI may be formed by forming an element isolation trench so as to expose the buried insulating layer 201 by patterning the active layer 202, and then filling an insulating material in the element isolation trench. As the element isolation layer STI is formed, the cell array region (see the reference symbol “CAR” in FIG. 5) may be defined.

Subsequently, the first back gate insulating pattern 111, the back gate electrode BG, the first shield isolation pattern 113, the first shield gate SG1, and the first shield capping pattern 115 may be sequentially formed.

Specifically, after a back gate trench BG_T is formed by removing some portions of the active layer 202 and the mask pattern MP, the first back gate insulating pattern 111 may be formed on the bottom surface and side surfaces of the back gate trench BG_T.

Subsequently, the back gate electrode BG may be formed by filling the back gate trench BG_T with a conductive material for forming the back gate electrode BG, and then, performing etch back on a portion of the conductive material. The back gate electrode BG may fill a portion of the back gate trench BG_T.

Subsequently, the first shield isolation pattern 113 may be formed on the back gate electrode BG by filling the back gate trench BG_T with an insulating material for forming the first shield isolation pattern 113 and then performing etch back on a portion of the insulating material. The first shield isolation pattern 113 may fill the portion of the back gate trench BG_T left after the formation of the back gate electrode BG.

Subsequently, the first shield gate SG1 may be formed on the first shield isolation pattern 113 by filling the back gate trench BG_T with a conductive material for forming the first shield gate SG1 and then performing etch back on a portion of the conductive material.

The thickness of the first shield gate SG1 in the third direction Z may be smaller than the thickness of the back gate electrode BG in the third direction Z. The first shield gate SG1 may fill the portion of the back gate trench BG_T left after the formation of the first shield isolation pattern 113.

Subsequently, the first shield capping pattern 115 may be formed on the first shield gate SG1 by filling the back gate trench BG_T with an insulating material for forming the first shield capping pattern 115 and then removing a portion of the insulating material by performing an etch back process or a planarization process.

The first shield capping pattern 115 may fill the remaining portion of the back gate trench BG_T left after the formation of the first shield gate SG1. The upper surface of the first shield capping pattern 115 may be substantially at the same level as that of the upper surface of the mask pattern MP and the element isolation layer STI.

In some embodiments, before the first back gate insulating pattern 111 is formed, the active layer 202 exposed by the back gate trench BG_T may be doped with an impurity by performing a gas-phase doping (GPD) process or a plasma doping (PLAD) process.

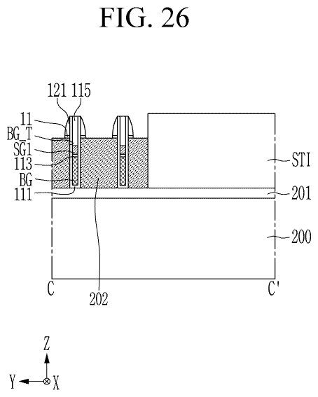

Subsequently, referring to FIG. 26 together with FIG. 25, a pair of spacer patterns 121 may be formed on both side surfaces of the first shield capping pattern 115 positioned inside the back gate trench BG_T by removing some portions of the mask pattern MP.

Specifically, the second mask pattern 12 of the mask pattern MP may be removed such that the first mask pattern 11 is exposed. Accordingly, the first shield capping pattern 115 may have a shape protruding from the upper surface of the first mask pattern 11.

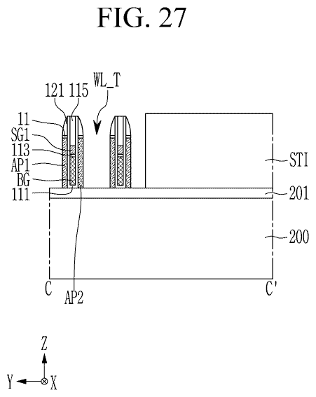

Subsequently, a spacer film (not shown in the drawings) may be formed along the upper surface of the first mask pattern 11, the side surfaces of the first back gate insulating pattern 111, and the upper surface of the first shield capping pattern 115, and then the spacer film may be patterned, whereby the spacer patterns 121 may be formed. Depending on the deposition thickness of the spacer film, the widths of active patterns (see the reference symbols “AP1” and “AP2” in FIG. 27) may be determined.

The spacer film may contain an insulating material. The spacer film may contain, for example, at least one of silicon oxide, silicon oxynitride, silicon nitride, silicon carbide (SiC), and silicon carbonitride (SiCN).

Subsequently, referring to FIG. 27 together with FIG. 26, a pair of first and second active patterns AP1 and AP2 may be formed by patterning the active layer 202.

Specifically, the active layer 202 may be patterned using the spacer patterns 121 as an etch mask. The step of patterning the active layer 202 may include, for example, a step of performing an anisotropic etching process on the active layer 202.

As the active layer 202 is patterned, a pair of first and second active patterns AP1 and AP2 which are positioned on both sides of the back gate electrode BG may be formed. The first and second active patterns AP1 and AP2 may be formed on the side surfaces of the first back gate insulating pattern 111.

In the process step of forming the first and second active patterns AP1 and AP2, as the active layer 202 is removed, the buried insulating layer 201 may be exposed. Although not shown in FIG. 27, in some embodiments, some portions of the patterned active layer 202 may remain on the side surfaces of the element isolation layer STI.

The first and second active patterns AP1 and AP2 adjacent to each other may define a word line trench WL_T. In other words, the word line trench WL_T may be formed between the first and second active patterns AP1 and AP2 adjacent to each other. The bottom surface of the word line trench WL_T may be defined by the buried insulating layer 201, and both side walls of the word line trench WL_T may be defined by the first and second active patterns AP1 and AP2.

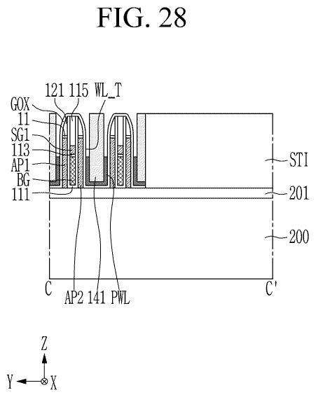

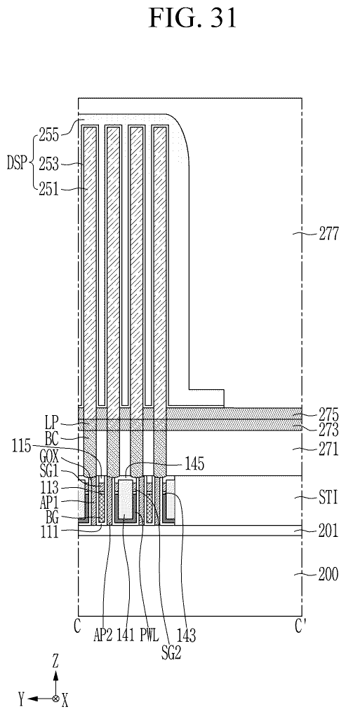

Subsequently, referring to FIG. 28 together with FIG. 27, a gate insulating pattern GOX, and a word line conduction film PWL for forming word lines (see the reference symbol “WL1” and “WL2” in FIG. 31) may be sequentially formed.

The gate insulating pattern GOX may be formed along the bottom surface and side walls of the word line trench WL_T so as to conform to them. The gate insulating pattern GOX may be formed along the side surfaces of the first and second active patterns AP1 and AP2, the upper surface of the first back gate insulating pattern 111, the upper surface of the first shield capping pattern 115, the upper surface of each spacer pattern 121, and the upper surface of the buried insulating layer 201 so as to conform to them.

The gate insulating pattern GOX may be formed using at least one of chemical oxidation method, a thermal oxidation method, a UV oxidation method, a dual plasma oxidation method, and physical vapor deposition (PVD), thermal chemical vapor deposition (thermal CVD), low pressure chemical vapor deposition (LP-CVD), plasma-enhanced chemical vapor deposition (PE-CVD), and atomic layer deposition (ALD) methods. However, the present disclosure is not limited thereto, and the method of forming the gate insulating pattern GOX may be variously changed.

The word line conduction film PWL may be formed along the surface of the gate insulating pattern GOX so as to conform to it. The word line conduction film PWL may be formed along the bottom surface and side walls of the word line trench WL_T so as to conform to them.

The word line conduction film PWL may contain a conductive material. For example, the word line conduction film may contain at least one of doped polysilicon, conductive metal nitrides, conductive metal silicon nitrides, metal carbonitrides, conductive metal silicides, conductive metal oxides, two-dimensional materials, and metals.

Subsequently, on the word line conduction film PWL, a gate isolation pattern 141 may be formed, and then some portions of the word line conduction film PWL may be removed.

Specifically, the gate isolation pattern 141 may be formed so as to entirely cover the word line conduction film PWL and fill the word line trench WL_T.

Subsequently, a portion of the gate isolation pattern 141 covering the word line conduction film PWL may be removed such that a portion of the word line conduction film PWL is exposed. In the process step of removing a portion of the gate isolation pattern 141, a portion of the gate insulating pattern GOX may be exposed.

Subsequently, an etching process on the exposed word line conduction film PWL may be performed.

For example, the etching process on the word line conduction film PWL may be a dry etch-back process.

The etching process on the word line conduction film PWL may be performed until the upper surface of the word line conduction film PWL is positioned substantially at the same level as that of the upper surface of the back gate electrode BG or positioned at a higher level than the upper surface of the back gate electrode BG. However, the present invention is not limited thereto, and in the etching process step on the word line conduction film PWL, the level of the upper surface of the word line conduction film PWL may be variously changed.

As a portion of the word line conduction film PWL is removed, the remaining word line conduction film PWL may have a roughly U-shaped cross section inside the word line trench WL_T. In other words, the removing word line conduction film PWL may be positioned along the bottom surface and side walls of the word line trench WL_T, and cover the bottom surface of the gate isolation pattern 141 and some portions of the side surfaces adjacent thereto.

As shown in FIG. 28, as the etching process is performed on the word line conduction film PWL, the upper surface of the word line conduction film PWL may be positioned at a lower level than the upper surface of the gate isolation pattern 141.

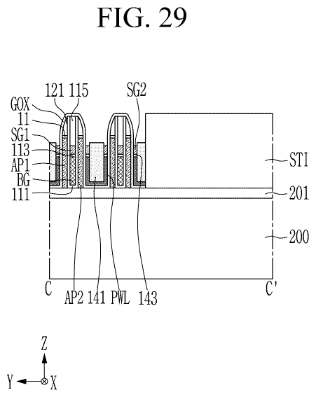

Subsequently, referring to FIG. 29 together with FIG. 28, a second shield isolation pattern 143 and a second shield gate SG2 may be sequentially formed on the word line conduction film PWL.

Specifically, an insulating material for forming the second shield isolation pattern 143 may be formed so as to fill the region between the gate isolation pattern 141 and the gate insulating pattern GOX positioned inside the word line trench WL_T, and then, the second shield isolation pattern 143 may be formed on the word line conduction film PWL by performing etch back on a portion of the insulating material.

In the process step of removing a portion of the second shield isolation pattern 143, a portion of the gate isolation pattern 141 may be removed together. However, the present disclosure is not limited thereto, and when the second shield isolation pattern 143 has high etch selectivity to the gate isolation pattern 141, in the process step of removing a portion of the second shield isolation pattern 143, a portion of the gate isolation pattern 141 may not be removed.

The second shield isolation pattern 143 may fill the portion between the gate isolation pattern 141 and the gate insulating pattern GOX left after the formation of the word line conduction film PWL.

The second shield isolation pattern 143 may be positioned substantially at the same level as that of the first shield isolation pattern 113 which is positioned on the back gate electrode BG. However, the present disclosure is not limited thereto, and in the process step of forming the second shield isolation pattern 143, the arrangement relationship between the first shield isolation pattern 113 and the second shield isolation pattern 143 may be variously changed.

Subsequently, a conductive material for forming a second shield gate SG2 may be formed so as to fill the region between the gate isolation pattern 141 and the gate insulating pattern GOX positioned inside the word line trench WL_T, and then a portion of the conductive material may be removed, such that the second shield gate SG2 is formed on the second shield isolation pattern 143.

The second shield gate SG2 may fill a portion of the region between the gate insulating pattern GOX and the gate isolation pattern 141 left after the formation of the second shield isolation pattern 143.

The second shield gate SG2 may be positioned substantially at the same level as that of the first shield gate SG1 which is positioned on the back gate electrode BG. However, the present disclosure is not limited thereto, and in the process step of forming the second shield gate SG2, the arrangement relationship between the first shield gate SG1 and the second shield gate SG2 may be variously changed.

In some embodiments, any one of the process step of forming the first shield isolation pattern 113 and the first shield gate SG1 and the process step of forming the second shield isolation pattern 143 and the second shield gate SG2 may be omitted.

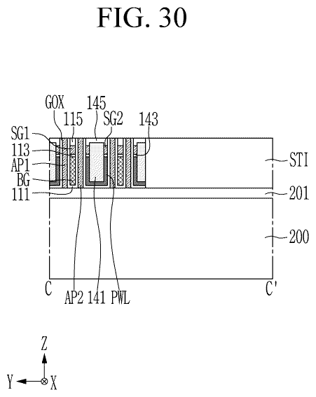

Subsequently, referring to FIG. 30, the second shield capping pattern 145 may be formed so as to cover the second shield gate SG2 and the gate isolation pattern 141.

Specifically, the second shield capping pattern 145 may be formed so as to entirely cover the second shield gate SG2 and the upper surface and side surfaces of the gate isolation pattern 141 adjacent to the second shield gate SG2.

The second shield capping pattern 145 may fill the word line trench (see the reference symbol “WL_T” in FIG. 28) left after the formation of the word line conduction film PWL, the second shield isolation pattern 143, and the second shield gate SG2.

Subsequently, after the second shield capping pattern 145 is formed, a planarization process step may be performed. In the step of performing the planarization process, the first mask pattern 11 and each spacer pattern 121 which are positioned on the first and second active patterns AP1 and AP2 may be removed such that the upper surfaces of the first and second active patterns AP1 and AP2 are exposed.

Further, in the step of performing the planarization process, a portion of the first back gate insulating pattern 111, a portion of the first shield capping pattern 115, a portion of the gate insulating pattern GOX, portions of the first and second active patterns AP1 and AP2, a portion of the second shield capping pattern 145, and a portion of the element isolation layer STI may be removed together.

Accordingly, the upper surface of the first back gate insulating pattern 111, the upper surface of the first shield capping pattern 115, the upper surface of the gate insulating pattern GOX, the upper surfaces of the first and second active patterns AP1 and AP2, the second shield capping pattern 145, and the upper surface of the element isolation layer STI may be substantially planarized.

Subsequently, referring to FIG. 31, on the upper surface of the first back gate insulating pattern 111, the upper surface of the first shield capping pattern 115, the upper surface of the gate insulating pattern GOX, the upper surfaces of the first and second active patterns AP1 and AP2, the second shield capping pattern 145, and the upper surface of the element isolation layer STI, the contact interlayer insulating layer 271 which includes a contact hole for explaining the first and second active patterns AP1 and AP2 may be formed.

Subsequently, inside the contact hole of the contact interlayer insulating layer 271, a plurality of buried contacts BC may be formed. The plurality of buried contacts BC may be formed on the first and second active patterns AP1 and AP2.

Subsequently, the pad isolation insulating layer 273 which includes a pad hole may be formed on the contact interlayer insulating layer 271, and then, inside the pad hole of the pad isolation insulating layer 273, a plurality of landing pads LP may be formed. The plurality of landing pads LP may be formed on the plurality of buried contacts BC.

Subsequently, on the pad isolation insulating layer 273, the contact etch stop layer 275 may be formed, and then, a first electrode 251 which passes through the contact etch stop layer 275 and is connected to the plurality of landing pads LP, a dielectric film 253 which covers the first electrode 251, and a second electrode 255 which is positioned on the dielectric film 253 may be sequentially formed. The first electrode 251, the dielectric film 253, and the second electrode 255 may constitute a cell capacitor DSP.

Subsequently, a third cell insulating layer 277 which entirely covers the cell capacitor DSP may be formed.

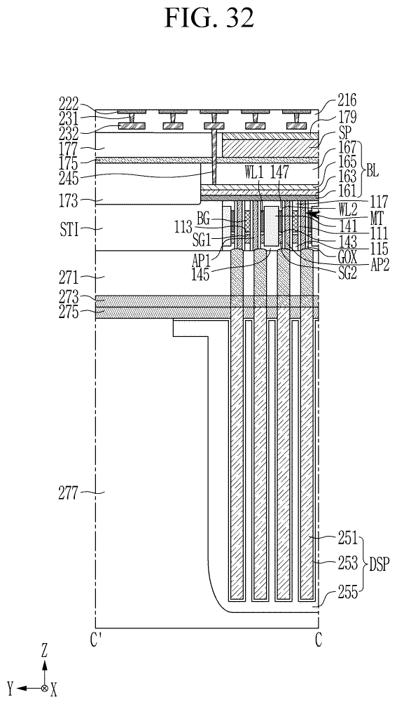

Subsequently, referring to FIG. 32 together with FIG. 31, a back surface lapping step of removing the sub substrate 200 may be performed. Removing the sub substrate 200 may include sequentially performing a grinding process and an etching process to expose the buried insulating layer 201.

Subsequently, the buried insulating layer 201 may be removed. As the buried insulating layer 201 is removed, the first and second active patterns AP1 and AP2, the gate insulating pattern GOX, and the first back gate insulating pattern 111 may be exposed.

Subsequently, the gate insulating pattern GOX and the first back gate insulating pattern 111 exposed may be removed. Accordingly, the back gate electrode BG and the word line conduction film PWL may be exposed.

Subsequently, a portion of the back gate electrode BG may be removed by performing an etch back process, and then, the second back gate insulating pattern 117 may be formed on the back gate electrode BG.

Further, a pair of first and second word lines WL1 and WL2 may be formed on both sides of the gate isolation pattern 141 by performing an etch back process or a patterning process for removing a portion of the word line conduction film PWL, and then, the gate capping pattern 147 may be formed so as to cover the first and second word lines WL1 and WL2 and the gate isolation pattern 141.

The process step of forming the second back gate insulating pattern 117 and the gate capping pattern 147 may include a step of performing a planarization process. Accordingly, the first and second active patterns AP1 and AP2, the first back gate insulating pattern 111, the second back gate insulating pattern 117, the gate insulating pattern GOX, and the gate capping pattern 147 may be substantially planarized.

Subsequently, on the active patterns AP1 and AP2, the polysilicon layer 161, the first metal layer 163, the second metal layer 165, and the bit line capping layer 167 may be sequentially formed. The polysilicon layer 161, the first metal layer 163, the second metal layer 165, and the bit line capping layer 167 may constitute a bit line BL.

Subsequently, the second cell insulating layer 173 may be formed on the element isolation layer STI, and then, on the bit line BL and the second cell insulating layer 173, the spacer insulating layer 175, the first cell insulating layer 177, the shield pattern SP, and the shield capping pattern 179 may be sequentially formed. However, the order in which the bit line BL, the second cell insulating layer 173, the spacer insulating layer 175, the first cell insulating layer 177, the shield pattern SP, and the shield capping pattern 179 are formed is not limited thereto, and may be variously changed.

Subsequently, on the first cell insulating layer 177 and the shield capping pattern 179, the second bonding insulating layer 216 may be formed.

Subsequently, the bit line contact 245 which is connected to the bit line BL may be formed. Subsequently, inside the second bonding insulating layer 216, the cell connection wiring line 232 which is connected to the bit line contact 245, the cell connection wiring contact 231, and the second bonding pad 222 may be formed.

In FIG. 32, it is shown that the second bonding insulating layer 216 is a single layer; however, the second bonding insulating layer 216 may have a structure in which a plurality of layers is stacked, and the plurality of layers may be formed by separate processes.

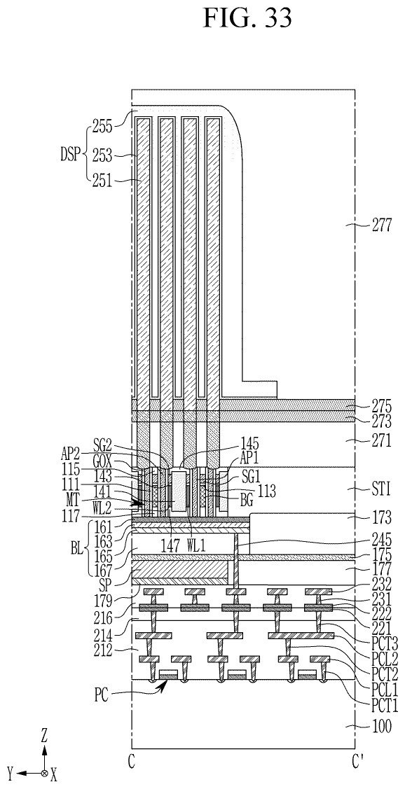

Subsequently, referring to FIG. 5 together with FIG. 33, on the substrate 100, the peripheral circuit structure PS which includes the peripheral circuit PC, the peripheral circuit contacts PCT1, PCT2, and PCT3, the peripheral circuit wiring lines PCL1 and PCL2, the peripheral circuit insulating layer 212, the first bonding insulating layer 214, and the first bonding pad 221 may be formed.

Subsequently, the first bonding pad 221 and the second bonding pad 222 may be bonded, and the first bonding insulating layer 214 and the second bonding insulating layer 216 may be bonded. Accordingly, the first bonding pad 221 and the second bonding pad 222 may be in contact with each other to form a metal bond, and the first bonding insulating layer 214 and the second bonding insulating layer 216 may be in contact with each other to form a junction insulating layer.

Subsequently, inside the third cell insulating layer 277, the first cell wiring contact 261 and the first cell wiring line 262 may be formed. Subsequently, on the third cell insulating layer 277, the fourth cell insulating layer 279, the second cell wiring contact 263 and the second cell wiring line 264 may be formed.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
a substrate;
a bit line that is positioned on the substrate and extends in a first direction;
a plurality of word lines that extend in a second direction intersecting the first direction;
a first active pattern and a second active pattern that are positioned between the plurality of word lines and spaced apart in the first direction;
a cell capacitor that is positioned on the first active pattern and the second active pattern; and
a plurality of shield gates that are positioned at a level between the plurality of word lines and the cell capacitor,
wherein each of the first active pattern and the second active pattern includes the following:
a first dopant region that is connected to the bit line;
a second dopant region that is connected to the cell capacitor; and
a channel region that is positioned between the first dopant region and the second dopant region, and
the plurality of shield gates overlap the second dopant region of at least one of the first active pattern and the second active pattern in the first direction.

2. The semiconductor device of claim 1, wherein:
the plurality of shield gates overlap the plurality of word lines in a vertical direction intersecting the first direction and the second direction.

3. The semiconductor device of claim 1, further comprising:
a back gate electrode that is positioned between the first active pattern and the second active pattern and extends in the second direction.

4. The semiconductor device of claim 3, wherein:
the plurality of shield gates include the following:
a first shield gate that overlaps the back gate electrode in a vertical direction intersecting the first direction and the second direction; and
a second shield gate that overlaps the plurality of word lines in the vertical direction.

5. The semiconductor device of claim 4, wherein:
the back gate electrode and the first shield gate are configured to be applied with different voltages, and
the plurality of word lines and the second shield gate are configured to be applied with different voltages.

6. The semiconductor device of claim 4, wherein:
the back gate electrode and the first shield gate are configured to be applied with a same voltage,
the plurality of word lines and the second shield gate are configured to be applied with a same voltage,
the first shield gate has a work function different from that of the back gate electrode, and
the second shield gate has a work function different from that of the plurality of word lines.

7. The semiconductor device of claim 1, further comprising:
an insulating isolation pattern that is positioned between the first active pattern and the second active pattern,
wherein the plurality of shield gates include the following:
a first shield gate that overlaps the isolation insulating pattern in a vertical direction intersecting the first direction and the second direction; and
a second shield gate that overlaps the plurality of word lines in the vertical direction.

8. A semiconductor device comprising:
a substrate that includes a cell array region and a peripheral circuit region;
a bit line that is positioned on the cell array region and extends in a first direction;
a plurality of word lines that extend in a second direction intersecting the first direction;
a first active pattern and a second active pattern that are positioned on the plurality of word lines and spaced apart in the first direction;
a back gate electrode that is positioned between the first active pattern and the second active pattern and extends in the second direction;
a cell capacitor that is positioned on the first active pattern and the second active pattern; and
a plurality of shield gates that overlap at least one of the plurality of word lines and the back gate electrode in a vertical direction intersecting the first direction and the second direction,
wherein each of the first active pattern and the second active pattern includes the following:
a first dopant region that is connected to the bit line;
a second dopant region that is connected to the cell capacitor; and
a channel region that is positioned between the first dopant region and the second dopant region, and
the plurality of shield gates overlap the second dopant region of at least one of the first active pattern and the second active pattern in the first direction.

9. The semiconductor device of claim 8, wherein:
the plurality of shield gates includes the following:
a first shield gate that overlaps the back gate electrode in the vertical direction; and
a second shield gate that overlaps the plurality of word lines in the vertical direction.

10. The semiconductor device of claim 9, wherein:
a width of the first shield gate and a width of the second shield gate are different.

11. The semiconductor device of claim 9, wherein:
a width of the second shield gate is smaller than a width of each of the plurality of word lines.

12. The semiconductor device of claim 11, wherein:
a width of the first shield gate is smaller than a width of the back gate electrode.

13. The semiconductor device of claim 9, wherein:
the plurality of word lines includes a first word line and a second word line adjacent to each other, and
the second shield gate overlaps the first word line and the second word line in the vertical direction.

14. The semiconductor device of claim 9, wherein:
an upper surface of the first shield gate and an upper surface of the second shield gate are positioned at different levels.

15. The semiconductor device of claim 9, wherein:
a thickness of the first shield gate and a thickness of the second shield gate are different.

16. The semiconductor device of claim 9, wherein:
in the peripheral circuit region, ends of the first shield gate and the back gate electrode are aligned at substantially the same boundary, and
the semiconductor device further includes the following:
a contact wiring line that is positioned in the peripheral circuit region;
a first contact via that is connected to the contact wiring line and the back gate electrode; and
a second contact via that is connected to the contact wiring line and the first shield gate and passes through the back gate electrode.

17. The semiconductor device of claim 9, wherein:
in the peripheral circuit region, the second shield gate and the plurality of word lines extend with different lengths so as to have a stepped structure, and
the semiconductor device further includes the following:
a word line contact that is positioned in the peripheral circuit region and connected to the plurality of word lines; and
a second shield gate contact that is positioned in the peripheral circuit region and connected to the second shield gate on an outer side than ends of the plurality of word lines.

18. A semiconductor device comprising:
a substrate that includes a cell array region and a peripheral circuit region;
a peripheral circuit structure that includes a peripheral circuit which is positioned on the substrate, and a peripheral circuit wiring line which is connected to the peripheral circuit; and
a cell structure that overlaps the peripheral circuit structure in a vertical direction,
wherein the cell structure includes the following:
a bit line that is positioned on the substrate and extends in a first direction intersecting the vertical direction;
a plurality of word lines that extend in a second direction intersecting the first direction and the vertical direction;
a plurality of active patterns that are positioned between the plurality of word lines and spaced apart in the first direction;
a back gate electrode that is positioned between the plurality of active patterns and extends in the second direction;
a cell capacitor that is positioned on the plurality of active patterns;
a first shield gate that overlaps the back gate electrode in the vertical direction; and
a second shield gate that overlaps the plurality of word lines in the vertical direction, and
each of the plurality of active patterns includes the following:
a first dopant region that is connected to the bit line;
a second dopant region that is connected to the cell capacitor; and
a channel region that is positioned between the first dopant region and the second dopant region, and
each of the first shield gate and the second shield gate overlaps the second dopant region in the first direction.

19. The semiconductor device of claim 18, wherein:
the peripheral circuit structure further includes a first bonding pad, and a first bonding insulating layer that surrounds the first bonding pad,
the cell structure further includes a second bonding pad, and a second bonding insulating layer that surrounds the second bonding pad, and
the first bonding pad is in contact with the second bonding pad, and the first bonding insulating layer is in contact with the second bonding insulating layer.

20. The semiconductor device of claim 18, wherein:
the cell structure further includes a memory cell and a cell connection wiring line which is connected to the memory cell, and
the semiconductor device further includes a through-hole via which connects the peripheral circuit wiring line and the cell connection wiring line.
